(19) United States
(12) Patent Application Publication
(10) Pub. No.: US 2007/0231927 A1
(43) Pub. Date: Oct. 4, 2007

(54) Semiconductor device and manufacturing method thereof

(76) Inventors: Koji Yamakawa, Tokyo (JP); Masahiro Kiyotoshi, Sagamihara-shi (JP); Soichi Yamazaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/729,918

(22) Filed: Mar. 30, 2007

(30) Foreign Application Priority Data
Apr. 3, 2006 (JP) 2006-102214

(51) Int. Cl. H01L 21/00

(52) U.S. Cl. 438/3

(57) ABSTRACT

A manufacturing method of a semiconductor device of an embodiment of the present invention includes: forming a lower electrode film for a capacitor above a substrate; forming a ferroelectric film on the lower electrode film by deposition-simultaneous crystallization; forming a dummy film on the ferroelectric film; removing the dummy film and a part of the ferroelectric film through a planarizing process to planarize the surface of the ferroelectric film; and forming an upper electrode film for the capacitor on the ferroelectric film.

### CROSS REFERENCE TO RELATED APPLICATION

This application is based upon and claims the benefit of priority from prior Japanese Patent Application No. 2006-102214, filed on Apr. 3, 2006, the entire contents of which are incorporated herein by reference.

### BACKGROUND OF THE INVENTION

1. Field of the Invention

The present invention relates to a semiconductor device and a manufacturing method thereof, for example, a semiconductor device including a ferroelectric memory (FeRAM: Ferroelectric Random Access Memory) including a ferroelectric capacitor and a manufacturing method thereof.

2. Background Art

In recent years, due to concerns about advantages such as nonvolatility, random access capability, miniaturization capability, lower power consumption, improved endurance, improved operation speed and the like, development of FeRAM is progressing. The FeRAM has a structure like the DRAM in which a paraelectric in a capacitor is replaced by a ferroelectric. A semiconductor device including a ferroelectric capacitor is disclosed in JP-A 2004-214569 (KOKAI) for example.

In general, the FeRAM employs, as a component of the capacitor, a ferroelectric thin film made of ferroelectric such as PZT (Pb(ZrₓTi₁₋ₓ)O₃), BIT (Bi₄Ti₃O₁₂), SBT (SrBi₂Ta₂O₉) or the like. Each of these ferroelectrics has a crystal structure based on a perovskite structure whose basic structure is an oxygen octahedron, and has residual polarization which gives nonvolatility to the FeRAM. In general, each of the ferroelectric thin films is deposited by employing a deposition process such as sol-gel method, sputtering method, MOCVD (Metal organic Chemical Vapor Deposition) method or the like, which can be consistent with a manufacturing process of a semiconductor device.

The ferroelectric capacitor of the FeRAM includes a ferroelectric thin film, an upper electrode, a lower electrode, and the like. When the ferroelectric thin film is deposited by employing ferroelectric such as PZT, BIT, SBT or the like, the ferroelectric crystallizes on the lower electrode. Therefore, the material and crystal structure of the lower electrode significantly influence the ferroelectric thin film. Furthermore, the material and crystal structure of the upper electrode significantly influence capacitor characteristics. In particular, the material and crystal structure of the upper electrode directly influence capacitor deterioration in the manufacturing process of the semiconductor device, reliability of the capacitor characteristics, and the like. Characteristics such as leakage characteristics, C to V characteristics, polarization characteristics, electric characteristics, retention characteristics, and fatigue characteristics of the capacitor, have close relations to the materials and the crystal structures of the upper electrode and the lower electrode.

On the other hand, as the size of the ferroelectric capacitor of the FeRAM is miniaturized from several micron □ (square) to submicron □ (square), the capacitor has come to suffer more process damage. Such process damage results from, for example, CVD in forming a hard mask for processing the capacitor, RIE in processing the capacitor, and CVD in forming an interlayer insulating film.

Therefore, it is requested to improve tolerance of the capacitor against the process damage, through improvement of the upper electrode. As described above, the miniaturization of the ferroelectric capacitor increases the process damage to the ferroelectric capacitor (capacitor deterioration). To realize high integration of the FeRAM, it is necessary to deal with such increase of the process damage to the ferroelectric capacitor, to prevent degradation of the reliability of the capacitor characteristics.

As the ferroelectric capacitor of the FeRAM is miniaturized, the capacitor deterioration and the degradation of the reliability of the capacitor characteristics become apt to occur, so that the polarization of the capacitor becomes unstable. Therefore, in recent years, to secure the characteristics and the reliability of the capacitor, it is examined to deposit a ferroelectric film by in-situ crystallization (deposition-simultaneous crystallization) of ferroelectric by MOCVD (Metal Organic Chemical Vapor Deposition) method. The MOCVD method has advantages such that deposition speed is high, lattice defects hardly occur in deposition, composition control is easy, required device configuration is simple, mass productivity is high, step coverage properties are high and the like, so that the film deposited by the MOCVD method has a high film quality. Furthermore, deposition by in-situ crystallization suppresses the occurrence of lattice defects on the interface between the ferroelectric film and the lower electrode, so that the amount of polarization increases, saturation characteristics are improved, and retention imprint deterioration is suppressed. Furthermore, deposition by in-situ crystallization suppresses the generation of bubbles (pores) in the film, so that a dense film is deposited. Such a dense film prevents invasion of hydrogen into the capacitor in fabricating the capacitor, so that the capacitor deterioration and the degradation of the reliability of the capacitor characteristics are suppressed.

However, the ferroelectric film deposited by in-situ crystallization of ferroelectric has a disadvantage that it has large irregularities on its surface. This causes problems such that shape control in the capacitor-processing (RIE) is difficult, the upper electrode is deposited to be uneven, the shape around the capacitor is difficult to stabilize, a capacitor leakage current increases and the like. The irregularities (roughness) on the surface of the ferroelectric film change according to deposition temperature, deposition condition, crystal orientation of the film, film thickness and the like. However, it is known that it basically shows the irregularities (roughness) of about 20 to 30% or more of the film thickness.

### SUMMARY OF THE INVENTION

An embodiment of the present invention is, for example, a manufacturing method of a semiconductor device, including:

forming a lower electrode film for a capacitor above a substrate;

forming a ferroelectric film on the lower electrode film by deposition-simultaneous crystallization;

forming a dummy film on the ferroelectric film;

removing the dummy film and a part of the ferroelectric film through a planarizing process to planarize the surface of the ferroelectric film; and

forming an upper electrode film for the capacitor on the ferroelectric film.

Another embodiment of the present invention is, for example, a manufacturing method of a semiconductor device, including:

forming a lower electrode film for a capacitor above a substrate;

forming a first ferroelectric film on the lower electrode film by deposition-simultaneous crystallization;

forming a second ferroelectric film on the first ferroelectric film by solution application method, by solution dipping method, by bias sputtering method, or by planarizing the surface of the second ferroelectric film through a planarizing process; and

forming an upper electrode film for the capacitor on the second ferroelectric film.

Another embodiment of the present invention is, for example, a manufacturing method of a semiconductor device, including:

forming a lower electrode film for a capacitor above a substrate;

forming, as a ground film, an oriented film oriented in a specific direction or a crystal film formed by crystallization of amorphous, on the lower electrode film; and

forming a ferroelectric film on the ground film by deposition-simultaneous crystallization.

Another embodiment of the present invention is, for example, a semiconductor device, including:

a lower electrode film for a capacitor formed on a substrate;

a first ferroelectric film formed on the lower electrode film and having irregularities on the top surface of the first ferroelectric film;

a second ferroelectric film formed between the first ferroelectric film and an upper electrode film for the capacitor, the maximum of irregularity height on the top surface of the second ferroelectric film being smaller than that of the first ferroelectric film; and

the upper electrode film for the capacitor formed on the second ferroelectric film.

### BRIEF DESCRIPTION OF THE DRAWINGS

FIG. 1 is a cross-sectional view showing a semiconductor device according to a first embodiment;

FIGS. 2A to 2F are cross-sectional views (1-6) showing a manufacturing method of the semiconductor device according to the first embodiment;

FIG. 3 is a cross-sectional view showing a semiconductor device according to a second embodiment;

FIGS. 4A to 4F are cross-sectional views (1-6) showing a manufacturing method of the semiconductor device according to the second embodiment;

FIG. 5 is a cross-sectional view showing a semiconductor device according to a third embodiment;

FIGS. 6A to 6E are cross-sectional views (1-5) showing a manufacturing method of the semiconductor device according to the third embodiment;

FIG. 7 is a cross-sectional view showing a semiconductor device according to a fourth embodiment;

FIGS. 8A to 8D are cross-sectional views (1-4) showing a manufacturing method of the semiconductor device according to the fourth embodiment;

FIG. 9 is a cross-sectional TEM image of a PZT film formed by in-situ crystallization of PZT by MOCVD method;

FIG. 10 is a cross-sectional view showing a semiconductor device according to a fifth embodiment; and

FIGS. 11A to 11F are cross-sectional views (1-6) showing a manufacturing method of the semiconductor device according to the fifth embodiment.

### DESCRIPTION OF THE EMBODIMENTS

### First Embodiment

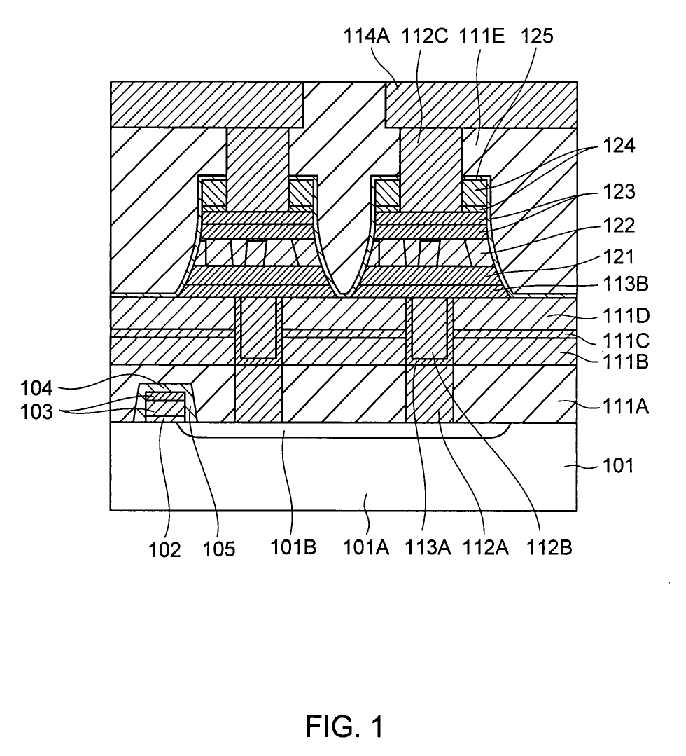

FIG. 1 is a cross-sectional view showing a semiconductor device according to a first embodiment.

The semiconductor device shown in FIG. 1 includes a substrate 101, a gate insulating film 102, a gate electrode film 103, a cap film 104 and a sidewall film 105. The substrate 101 is a silicon substrate. The substrate 101 has a diffusion layer 101A of a first conductivity type (P-type for example) and a source/drain diffusion layer 101B of a second conductivity type (N-type for example). The gate insulating film 102 is made of a silicon dioxide film, and is formed on the substrate 101. The gate electrode film 103 is made of laminated layers including a lower layer made of a polysilicon film and an upper layer made of a tungsten silicide (WSi₂) film, and is formed on the gate electrode film 102. The cap film 104 is made of a silicon nitride film, and is formed on the top surface of the gate. The sidewall film 105 is made of a silicon nitride film, and is formed on the side surface of the gate. A MOS-type field effect transistor is formed by these members and the like on the diffusion layer 101A (substrate 101).

The semiconductor device shown in FIG. 1 includes first, second, third and fourth interlayer insulating films 111A, 111B, 111C and 111D, first and second plug layers 112A and 112B, and first and second barrier layers 113A and 113B. The interlayer insulating films 111A, 111B, 111C and 111D are made of a silicon dioxide film, a silicon dioxide film, a silicon nitride film and a silicon dioxide film respectively, and are formed to cover the transistor. The plug layers 112A and 112B are made of a polysilicon layer and a tungsten (W) layer respectively. The barrier layers 113A and 113B are made of a Ti layer and/or a TiN layer, and a TaSiN layer and/or a TiAlN layer respectively.

The semiconductor device shown in FIG. 1 includes a lower electrode film 121 for a capacitor, a ferroelectric film 122, an upper electrode film 123 for the capacitor, a mask film 124 and a cover film 125. The lower electrode film 121 is made of an Ir (iridium) film, and is formed on the barrier layer 113B. The ferroelectric film 122 is made of a PZT film formed by in-situ crystallization of PZT by MOCVD method, and is formed on the lower electrode film 121. The upper electrode film 123 is made of laminated layers including a lower layer made of an SRO (SrRuO₃) film and an upper layer made of an IrOₓ (iridium oxide) film, and is formed on the ferroelectric film 122. The mask film 124 is made of laminated layers including a lower layer made of an aluminum oxide film and an upper layer made of a silicon dioxide film, and is formed on the upper electrode film 123. The cover film 125 is made of an aluminum oxide film or a silicon nitride film, and is formed to cover the barrier layer 113B, lower electrode film 121, ferroelectric film 122, upper electrode film 123 and mask film 124. A stack-type ferroelectric capacitor is formed by these members and the like on the source/drain diffusion layer 101B (substrate 101).

The semiconductor device shown in FIG. 1 includes a fifth interlayer insulating film 111E, a third plug layer 112C and a first wiring layer 114A. The interlayer insulating film 111E is made of a silicon dioxide-film, and is formed to cover the capacitor. The plug layer 112C is made of a W (tungsten) layer, an Al (aluminum) layer, a Cu (copper) layer or an Al—Cu alloy layer. The wiring layer 114A is made of an Al (aluminum) layer, a Cu layer or an Al—Cu alloy layer.

The plug layer 112A is formed to contact the source/drain diffusion layer 101B. The plug layer 112B is electrically connected to the plug layer 112A via the barrier layer 113A. The plug layer 112B is electrically connected to the lower electrode film 121 via the barrier layer 113B. The plug layer 112C is electrically connected to the upper electrode film 123. The plug layer 112C is electrically connected to the wiring layer 114A.

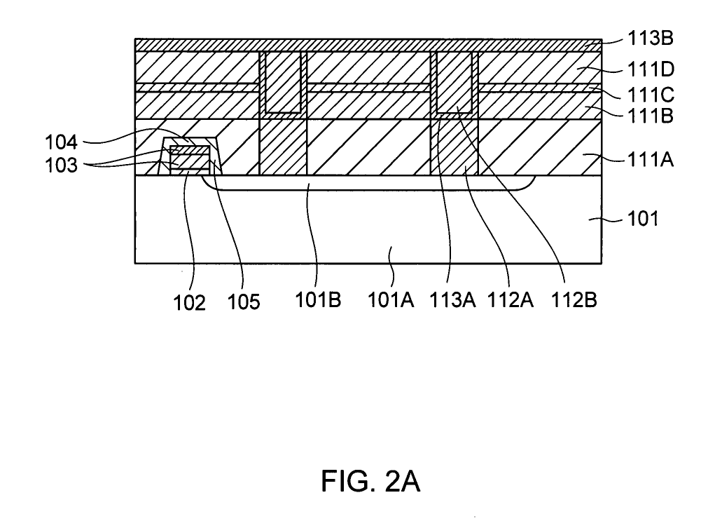

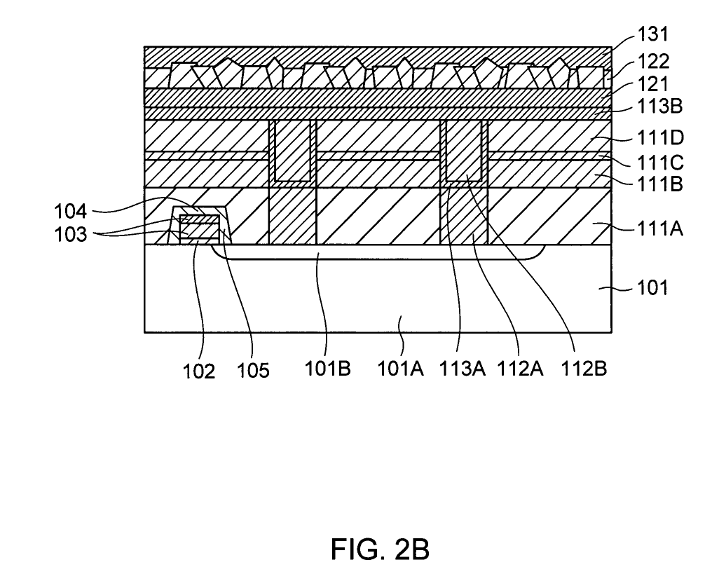

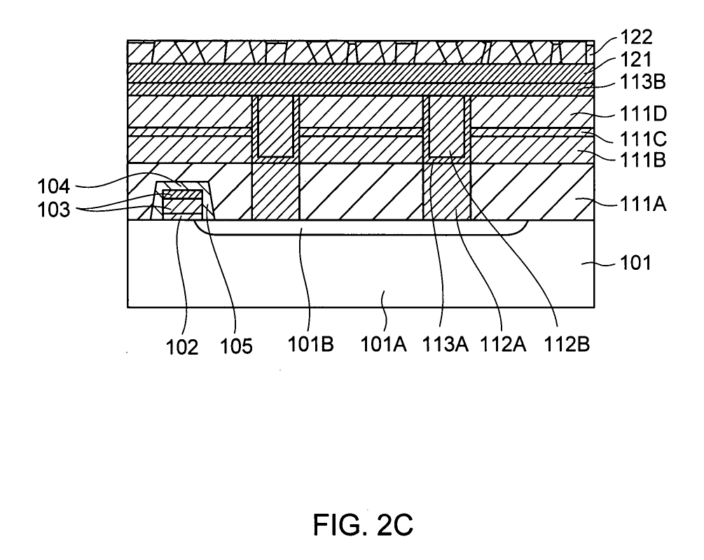

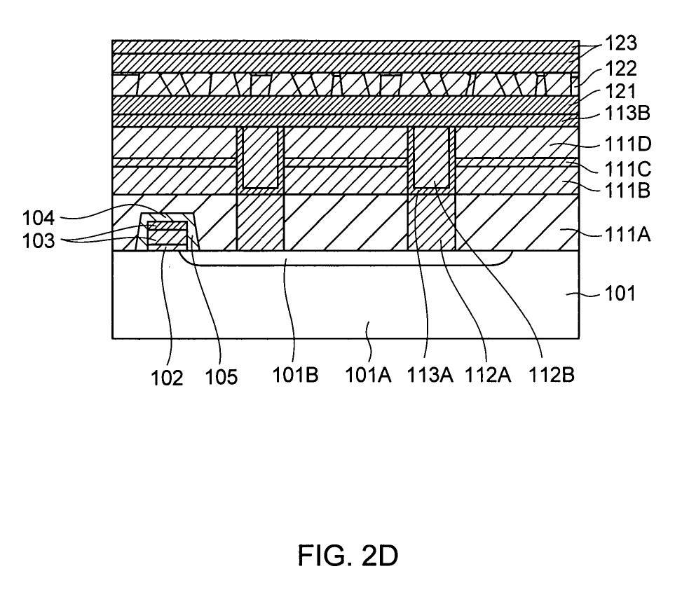

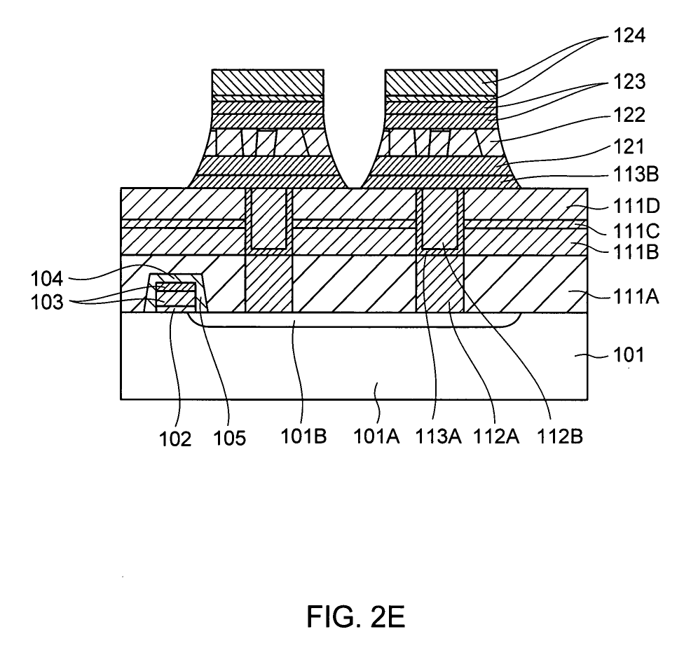

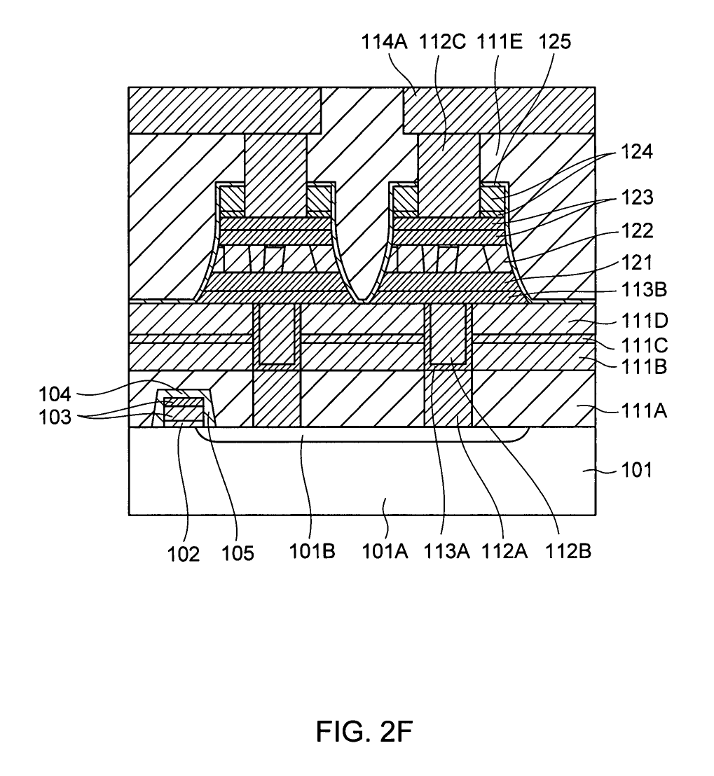

FIGS. 2A to 2F are cross-sectional views showing a manufacturing method of the semiconductor device according to the first embodiment.

First, as shown in FIG. 2A, a gate insulating film 102, a gate electrode film 103, a cap film 104, a sidewall film 105, interlayer insulating films 111A, 111B, 111C and 111D, plug layers 112A and 112B, and barrier layers 113A and 113B are formed on (or above) a substrate 101 by known methods. A diffusion layer 101A and a source/drain diffusion layer 101B are also formed by known methods.

Next, as shown in FIG. 2B, under the condition that the barrier layer 113B is deposited over the entire surface, an Ir film (lower electrode film 121) is formed on the barrier layer 113B by sputtering method or CVD method. The Ir film is deposited over the entire surface. Then, a PZT film (ferroelectric film 122) is formed on the Ir film by in-situ crystallization of PZT by MOCVD method, using liquid material such that metallo-organic complex is melted in liquid. Thereby, irregularities due to the in-situ crystallization are formed on the surface of the PZT film. The PZT film is deposited over the entire surface. Then, a dummy film 131, which is used as a dummy, is formed on the PZT film. The dummy film 131 is deposited over the entire surface. The dummy film 131 may be a conductor film or a dielectric film (e.g. ferroelectric film) for example, and may be formed by sol-gel method, sputtering method or CVD method for example.

Next, as shown in FIG. 2C, all or a part of the dummy film 131 and a part of the ferroelectric film 122 are removed through a planarizing process by CMP method (chemical mechanical polishing method) or etch-back method, to planarize the surface of the ferroelectric film 122. Thereby, the irregularities on the surface of the ferroelectric film 122 are planarized. The dummy film 131 may be entirely removed or not entirely removed. However, in the case where the dummy film 131 partially remains, it is desirable that the dummy film 131 be a ferroelectric film (particularly, a ferroelectric film of the same composition as the ferroelectric film 122). In this embodiment, with regard to the semiconductor device which includes the high-quality ferroelectric film 122 crystallized by deposition-simultaneous crystallization, the dummy film 131 is planarized, or the ferroelectric film 122 is planarized via planarizing the dummy film 131. Therefore, it is possible to prevent the occurrence of interface defects in the ferroelectric film 122 due to the stress on the electrode interface by CMP, and prevent the adhesion of residues of CMP, so as to further suppress the deterioration of electric characteristics.

Next, as shown in FIG. 2D, an SRO film (lower layer of upper electrode film 123) is formed on the PZT film by sputtering method or CVD method. The SRO film is deposited over the entire surface. In the case where the SRO film is deposited in an amorphous state, an annealing process such as RTA is performed for crystallization of the SRO film. Then, an IrOₓ film (upper layer of the upper electrode film 123) is formed on the SRO film by sputtering method or CVD method. The IrOₓ film is deposited over the entire surface. In a reducing atmosphere such as hydrogen, the IrOₓ film works as a self-reduced buffer film, and shows high barrier properties against oxygen. Laminated films of the SRO film and IrOₓ film have advantages that the barrier properties against reducing gas are intensified, diffusion of Ir generated by reduction of the IrOₓ into the PZT film is prevented, and the like. The IrOₓ film may undergo densification, crystallization and the like by a thermal process after deposition.

Next, an aluminum oxide film (lower layer of mask film 124) is formed on the IrOₓ film by sputtering method or CVD method. The aluminum oxide film is deposited over the entire surface. Then, a silicon dioxide film (upper layer of the mask film 124) is formed on the aluminum oxide film by sputtering method or CVD method. The silicon dioxide film is deposited over the entire surface. Then, as shown in FIG. 2E, the upper layer of the mask film 124 is processed by an etching by photolithography method and RIE method. Then, the lower layer of the mask film 124, the upper layer of the upper electrode film 123, the lower layer of the upper electrode film 123, the ferroelectric film 122, the lower electrode film 121 and the barrier layer 113B are processed by an etching by RIE method.

Next, as shown in FIG. 2F, an aluminum oxide film (cover film 125) is formed on the mask film 124 by sputtering method or CVD method. The aluminum oxide film is deposited over the entire surface. Then, a silicon dioxide film (interlayer insulating film 111E) is formed on the aluminum oxide film by sputtering method or CVD method. The silicon dioxide film is deposited over the entire surface. Then, a part of the interlayer insulating film 111E is removed through a planarizing process by CMP method or etch-back method, to planarize the surface of the interlayer insulating film 111E. Then, the interlayer insulating film 111E, the cover film 125, the upper layer of the mask film 124 and the lower layer of the mask film 124 are processed by an etching by photolithography method and RIE method, to form a contact hole for embedding a plug layer 112C. Then, the interlayer insulating film 111E is processed by an etching by photolithography method and RIE method, to form a trench for embedding a wiring layer 114A. Then, an annealing process (annealing conditions are oxygen atmosphere, 600 to 650° C., 30 to 60 minutes for example) is performed for recovery of the PZT film from damage. If the damage is slight, this annealing process may be omitted. Then, member for forming the plug layer 112C and the wiring layer 114A is embedded in the contact hole and the trench by sputtering method or CVD method, to form the plug layer 112C and the wiring layer 114A of a dual damascene structure for connecting adjacent capacitors.

In the first embodiment, due to the in-situ crystallization, the surface of the ferroelectric film 122 is irregular, immediately after the ferroelectric film 122 is formed. However, due to the planarizing process, the surface of the ferroelectric film 122 becomes flat, before the upper electrode film 123 is formed on the ferroelectric film 122. Therefore, the surface of the upper electrode film 123, that is, the interface between the upper electrode film 123 and its upper conductive layer (plug layer 112C), also becomes flat. This improves a joint between the upper electrode film 123 and its upper conductive layer (plug layer 112C). With regard to the flatness of the surface of the upper electrode film 123, it is desirable that the mean roughness of the irregularities (minute irregularities) on the surface of the upper electrode film 123 be 2.0 to 5.0 nm. Thereby, focus in lithography for the upper electrode film 123 becomes even. Further, the RIE processing of the capacitor becomes easier, so that the side surface of the capacitor can be processed to be even. Further, in terms of the electric characteristics and reliability, reducing damage from upward cannot be suffered easily, because coverage of the upper electrode becomes even. Further, it is also possible to suppress adverse influences such that, resulting from the occurrence of electrostatic concentration in a thin part of the ferroelectric film, a leakage current increases, withstand voltage reduces, fatigue characteristics deteriorate, and retention characteristics degrade. These preferred effects become particularly conspicuous when the thickness of the ferroelectric film becomes about 100 nm or less. In addition to these examples, the above-mentioned various adverse influences which the ferroelectric film 122 formed by the in-situ crystallization has on the semiconductor device, are prevented by the planarizing process of the ferroelectric film 122, which improves the reliability of the semiconductor device and the yield of a product of the semiconductor device.

The following description will describe details and variations of the lower electrode film 121.

Conventionally, a Ti/Pt laminated film (film thickness is 20 nm/200 nm for example) was mainstream as a material of the lower electrode film 121. With regard to the structure of the lower electrode film 121, a COP structure in which the lower electrode film 121 is formed on the contact plug for the lower electrode, is going mainstream lately to reduce the capacitor size. Doped polysilicon and tungsten are used for a connecting plug. However, a thermal process in oxygen atmosphere such as RTO is required in a crystallization process of the ferroelectric film 122, so that there arises a problem of oxidation of the surface of the connecting plug through the lower electrode film 121. For the purpose of preventing the oxidation, Ir-type metals are used as the materials of the lower electrode film 121. For example, they are a Ti/Ir laminated film, a TiAlN/Ir laminated film, a Ti/Ir/IrO₂/Pt laminated film and the like. It is also possible to form, on an Ir film or a Pt film, a conductive oxide film having a perovskite crystal lattice such as SrRuO₃, LaNiO₃, (La, Sr) CoO₃, or YBCO, or a conductive oxide film made of a noble metal oxide such as IrO₂, RuO₂, or RhO₂. It is possible, by having these conductive oxides lie between noble metal electrodes, to improve the fatigue characteristics, imprint characteristics and retention characteristics of the capacitor. This is firstly because the oxygen is supplied on the interface from the conductive oxide film to the ferroelectric film 122 to compensate for oxygen loss of the ferroelectric film 122. It is secondly because the material of the same crystal structure as the ferroelectric film 122 or the material capable of lattice matching therewith is used as the material of the conductive oxide film to structurally and electrically improve the interface between the ferroelectric film 122 and the conductive oxide film.

The following description will describe details and variations of the ferroelectric film 122.

The ferroelectric film 122 is formed on the lower electrode film 121 by deposition with simultaneous crystallization using the MOCVD method. With regard to the MOCVD of a high-permittivity film and the ferroelectric film, vapor pressure of the material is generally low. Therefore, a solution vaporization method is widely used, which is the method for melting a metallo-organic complex material in an organic solvent, leading it into a carburetor in a solution state at normal temperature and forcibly vaporizing it. In comparison with a solid sublimation method, the solution vaporization method has advantages that it is easy to control a material supply, it is possible to increase deposition speed of the high-permittivity film and the ferroelectric film by increasing the material supplies, it is possible to monitor a remaining amount of the solution with a level sensor, and the like. The conditions of an MOCVD material are as follows: selective deposition should be easy, a high-purity film should be formable with little amounts of carbon and particles remaining in the film, vapor pressure when it is a liquid should be high and its supply should be easy, it should be stable and storable without changing over time, its toxicity should be low enough to be safe to an environment and a human body, and the like. The ferroelectric film 122 has the irregularities of which maximum roughness is 50 to 150 nm for example (80 nm for example) formed on its surface.

In the case of forming a PZT-type film as the ferroelectric film 122 for example, Pb (dpm) 2, Zr (dpm) 4, Zr (O.t—C4H9) 4, Ti (O.i—C3H7) 4 and the like are used as the materials of the ferroelectric film 122. These materials are dissolved in THF (tetrahydrofuran) to be liquid materials. Subsequently, the liquid materials are gasified by pumping inactive gases such as He and Ar as carrier gases and spraying them to the carburetor. Subsequently, oxygen, dinitrogen monoxide and the like as oxidizers are introduced into a chamber via a shower plate so as to deposit the ferroelectric film 122 on the substrate 101 inside the chamber. A solution including Pb, Zr and Ti (cocktail source) may also be used as the material of the ferroelectric film 122. In this case, temperature of the substrate 101 is set as 400 to 650° C., and the composition of the PZT film is controlled by controlling gas supplies. For example, control is exerted so that a ratio of Pb becomes about 1.15 as an A/B ratio and a Zr/Ti ratio becomes 35/65 so as to deposit the PZT film. In this case, a deposition condition for crystallizing the PZT as the PZT film of a perovskite structure is applied. Here, the PZT is crystallized simultaneously with deposition (in-situ crystallized), which suppresses defect formation on the interface between the lower electrode film 121 and the ferroelectric film 122, such as positive ion excess, positive ion loss and oxygen loss. This leads to prevention of deterioration of the ferroelectric characteristics, fatigue characteristics, imprint characteristics and retention characteristics. The thickness of the ferroelectric film 122 is 70 to 150 nm here.

In the case of forming an SBT-type film as the ferroelectric film 122 for example, Sr (dpm) 2/THF, Bi (C6H5) 3, Bi (CH3) 3, Bi (C2H5) 3, a solid material having phenyl and tolyl, Ta (OC2H5) 5, Nb (OC2H5) 5, Ta (C2H5) 5 and the like are used as the materials of the ferroelectric film 122. These liquid materials are gasified by pumping them with the inactive gases such as He and Ar as the carrier gases and spraying them to the carburetor. Or else, these liquid materials are introduced into the carburetor by a bubbling method. Subsequently, oxygen, dinitrogen monoxide and the like as the oxidizers are introduced into the chamber via the shower plate so as to deposit the ferroelectric film 122 on the substrate 101 inside the chamber. A solution including Sr, Bi, Ta and Nb (cocktail source) may also be used as the material of the ferroelectric film 122. In this case, the temperature of the substrate 101 is set as 400 to 650° C., and the composition of the PZT film is controlled by controlling gas supplies. In this case, a deposition condition for crystallizing the SBT or SBTN as the SBT film or SBTN film of a Bi layer compound structure is applied. Here, the SBT or SBTN is crystallized simultaneously with deposition (in-situ crystallized), which suppresses the defect formation on the interface between the lower electrode film 121 and the ferroelectric film 122, such as the positive ion excess, positive ion loss and oxygen loss. This leads to prevention of deterioration of the ferroelectric characteristics, fatigue characteristics, imprint characteristics and retention characteristics. The thickness of the ferroelectric film 122 is 70 to 150 nm here.

With regard to specific examples of the ferroelectric film 122, a BIT-type film (Bi₄Ti₃O₁₂ or the like) can be named in addition to the PZT-type film (Pb (ZrₓTi₁₋ₓ) O₃ or the like) and the SBT-type-film (SrBi₂Ta₂O₉ or the like).

The following description will describe details and variations of the dummy film 131.

The dummy film 131 is formed on the surface of the ferroelectric film 122 having the irregularities formed thereon by using a CSD (Chemical Solution Deposition) method such as sol-gel method. The dummy film 131 is desirably the ferroelectric film of the same composition as the ferroelectric film 122. However, it may also be a ferroelectric film of a different composition from the ferroelectric film 122 or a dielectric film of a dielectric other than the ferroelectric (BST ((Ba, Sr) TiO₃), STO (SrTiO₃) SiN (SiNₓ), SiO₂, TiO₂, Al₂O₃ or the like). While the dummy film may be entirely removed, it may also partially remain. By partially remaining, it is possible to buffer, by the irregularities on the interface between the ferroelectric film and the dummy film, a lattice strain in the portion of the irregularities. It is also possible to reduce, by the dummy film, the leakage current generated through grain boundaries of the ferroelectric film. It is particularly desirable to render the dummy film 131 as the ferroelectric film, in the case where the dummy film 131 remains in hollows and gaps of the crystal constituting the ferroelectric film 122, after planarizing the surface of the ferroelectric film 122 as shown in FIGS. 1 and 2. In the case where the dummy film is the ferroelectric film, a sufficient amount of polarization can be secured. In the case where the dummy film 131 has the same composition as the ferroelectric film 122, they have the same coercive force so as to have the effects that the leakage current generated due to a difference in the coercive force between the films is small and breakdown voltage is high. In the case where the dummy film 131 is the ferroelectric film of a different composition from the ferroelectric film 122, it has the effects of allowing control to be exerted over a behavior of a domain wall on the interface portion of the ferroelectric film and the dummy film, to change the coercive force and improve saturation characteristics so as to increase an amount of signals. In the case where, as an example of the dummy film 131 being the ferroelectric film of a different composition from the ferroelectric film 122, a lower layer film of a capacitor insulator is a Zr-rich film and an upper layer film is a Ti-rich film, such as when the ferroelectric film 122 is a PZT-type film of which Zr/Ti is 60/40 while the dummy film 131 is a PZT-type film of which Zr/Ti is 40/60, it has the effects that the stress and strain exerted to a crystal film around a lower electrode interface can be reduced while having a large amount of polarization and a good squareness ratio as the characteristics of the Ti-rich film. In the case where the lower layer film of the capacitor insulator is a more Ti-rich film than the upper layer film, such as when the first ferroelectric film 122 is a PZT-type film of which Zr/Ti is 30/70 while the second ferroelectric film 122B is a PZT-type film of which Zr/Ti is 40/60, it has the effects that the PZT film can be more easily oriented in accordance with the orientation of the lower electrode (111 orientation for example) so as to increase the amount of polarization and improve the saturation characteristics. In the case where the dummy film 131 is the SBT film, an amorphous film is deposited on the ferroelectric film 122 by a solution application method such as sol-gel method using alkoxide including Sr and Ta and acetic acid Bi hydrate, or MOD method using a carboxylic acid metallic salt. After the amorphous film desiccates, crystallization annealing is performed in oxygen atmosphere by a process such as RTO. In this case, it is also possible to repeat the application, desiccation, and crystallization annealing process. In the case where the dummy film 131 is a dielectric film such as SiO₂ or TiO₂, it is possible to form the dummy film 131 by solution application method such as sol-gel method or MOD method, solution dipping method, sputtering method such as bias sputtering method, CVD method such as mist CVD method, evaporation method or the like. Similarly, it is possible to form the dummy film 131 by these methods in the case where the dummy film 131 is the ferroelectric film. In the case where the dummy film 131 is deposited by solution application method, solution dipping method, or bias sputtering method, the dummy film 131 having a flat surface is deposited. The mean roughness (Ra) of the irregularities on the surface of the dummy film 131 is about a few nm which is 5 nm or less. This value is smaller than the mean roughness of the irregularities on the surface of an MOCVD film.

Subsequently, etch-back or polishing is performed to the dummy film 131 by a technique of the RIE, CMP or the like, so as to expose the ferroelectric film 122 on the surface of the substrate 101. In the case of using the RIE, a selection ratio between the ferroelectric film 122 and the dummy film 131 is reduced to perform the etch-back evenly over the entire surface, by the methods such as setting the temperature between 200 to 300° C., using a chlorine or fluorine gas, and applying a bias voltage, so that the Ra of the surface (exposed surface) of the ferroelectric film 122 becomes 5 nm or less. In the case of using the CMP, the ferroelectric film 122 is exposed on the surface of the substrate 101 by planarizing the surface of the dummy film 131, so as to set the Ra of the surface (exposed surface) of the ferroelectric film 122 at 5 nm or less. In these planarizing processes, the ferroelectric film 122 is exposed to improve capacitor characteristics. However, if the deterioration of the capacitor characteristics is within an allowable range, the dummy film 131 may remain on a part of the ferroelectric film 122. It is also possible, after the planarizing process, to perform the annealing process for the purpose of recovering from crystal structure damage on the ferroelectric film surface caused in the planarizing process. For example, it is possible to restore the perovskite structure which has become defective, by an RTO process at 600° C.

The following description will describe details and variations of the upper electrode film 123.

A noble metal film made of a noble metal such as Pt or Ir is used as the upper electrode film 123 in many cases. However, it is also possible to use, as the upper electrode film 123, a conductive oxide film made of a conductive oxide having the perovskite structure of an ABOₓ type (A and B are metal elements, O is an oxygen element, and x is a natural number), a conductive oxide film made of a conductive oxide of an MOₓ type (M is a metal element, O is an oxygen element, and x is a natural number), or a laminated film including these films, in order to suppress the damage to the capacitor in the CVD-processing of the mask film 124 and the interlayer insulating film 111E, in the RIE-processing of the capacitor, and in the sintering-processing in a forming gas. Many of the conductive oxides of the ABOₓ type have the perovskite structure. With regard to representative examples of the metal element A, alkaline-earth metals such as Pb, Ba, Sr and Ca can be named. With regard to representative examples of the metal element B, the metal elements such as Ti, Nb, Mg, Zr, Zn, Ta, W and Mn can be named. The “x” of ABOₓ is typically “3,” which is changeable depending on whether the oxygen is in excess or in loss. With regard to specific examples of the conductive oxides of the ABOₓ type, the SrRuO₃ (SRO), LaNiO₃ (LNO), (La, Sr) CoO₃ and YBCO (superconductor) can be named. With regard to a specific example of the upper electrode film 123, a laminated film of SRO and IrOₓ can be named. It is possible to use a conductive film made of a metal oxide, even if not the perovskite structure or the MOₓ type. Defects such as oxygen losses on the interface between the ferroelectric film 122 and the upper electrode film 123, significantly influences tolerance to reducing process damage, deterioration of fatigue characteristics, deterioration of retention and deterioration of imprint, in a capacitor manufacturing process thereafter.

The following description will describe the capacitor of this embodiment.

The capacitor of a size of 0.5 μm×0.5 μm or less was manufactured as described above, and consequently the amounts of polarization (amounts of residual polarization, polarization inversion charge, switching charge, and the like) was 30 μC/cm² or more, so that sufficient amounts of polarization could be secured even in consideration of the fatigue, retention, and imprint characteristics. Similarly, the capacitor of a size of 0.3 μm×0.3 μm or less was manufactured, and consequently the amounts of polarization was 20° C./cm² or more, so that sufficient amounts of polarization could be secured even in consideration of the fatigue, retention, and imprint characteristics.

A ferroelectric memory including a ferroelectric capacitor (FeRAM) and an embedded memory require reduction in a capacitor cell size in conjunction with higher integration of the memory. When reducing the capacitor cell size, space of the capacitor occupied inside a chip must be reduced while securing the amount of signals necessary to operate the semiconductor device without a problem. However, to reduce the capacitor cell size, there is a problem that it significantly influences back-end damage.

However, according to the first embodiment, it is possible to manufacture the capacitor of which interface between the ferroelectric film 122 and the upper electrode film 123 is flat. Therefore, it is possible to realize the capacitor such that the reliability of ferroelectric characteristics, imprint, retention, and the like is good, tolerance to process damage is strong, leakage current is little, and characteristics of capacitors are even. Furthermore, insulation tolerance of the capacitor is improved by the effects of the planarization of the surface of the ferroelectric film 122. According to experiment, the value of the insulation tolerance of the capacitor increased by two digits.

Further, according to the first embodiment, it is possible to reduce the defects of the interface between the ferroelectric film 122 and the lower electrode film 121, and it is also possible to achieve reduction in the leakage current and increase in the withstand voltage by decreasing the surface roughness of the ferroelectric film 122. Furthermore, it is possible, because of the precise ferroelectric film 122 formed by the MOCVD method, to obtain the capacitor with little process deterioration and obtain a sufficient capacitor signal amount with small capacitor space. To be more specific, it is possible to secure submicron capacitor characteristics by the ferroelectric film 122, and improve the process damage tolerance. In this way, according to the first embodiment, it is possible to reduce the deterioration of the capacitor characteristics due to the back-end damage in the manufacturing process of the semiconductor device, so as to improve the reliability of the semiconductor device.

The following description will describe a high-temperature RIE processing of the capacitor of this embodiment.

In general, in the case of performing an RIE processing of a ferroelectric capacitor which employs noble metal, a capacitor of a small taper angle is manufactured, because processing of Pt film, Ir film, and the like is difficult (It is difficult to form a kind of gases having high vapor pressure. A fence made of noble metal is formed on the capacitor side). However, such a small taper angle makes it difficult to form a minute capacitor. Therefore, to realize a high-density FeRAM, it is necessary to manufacture a capacitor of a larger taper angle. As a method for realizing this purpose, high-temperature RIE processing of the ferroelectric capacitor is considered. Here is given a description about a specific example of the high-temperature RIE processing of the ferroelectric capacitor.

First, after the deposition of the mask film 124, the mask film 124 is RIE-processed by using photoresist, in the form of a processing mask for the capacitor. The RIE processing is performed at a room temperature by using a halogen gas such as CHF₃ or CF₄. Next, the photoresist used for the RIE processing of the mask film 124 is removed by an ashing process. Next, the upper electrode film 123 is RIE-processed by using the mask film 124. A halogen gas is used for the RIE processing. The RIE processing is performed by using a mixed gas of Cl₂, O₂, Ar and the like and setting the substrate 101 at a high temperature of 250 to 400° C.

Next, the high-temperature RIE processing of the ferroelectric film (PZT film) 122 is performed likewise by using a mixed gas based on the halogen gases of Cl₂, CF₄, O₂, Ar and the like. Next, the lower electrode film 121 is processed. Here, the lower electrode film 121 is the Ti/Ir laminated film. With regard to the Ir film of the lower electrode film 121, the high-temperature RIE processing is performed through the same process as the ferroelectric film 122. With regard to the Ti film of the lower electrode film 121, the high-temperature RIE processing is performed by using a mixed gas of Cl₂ and Ar. The mask film 124 is thick enough to maintain the form of the mask film 124 until completion of the processing of the lower electrode film 121. Therefore, the form of the mask film 124 is maintained, even though the thickness of the mask film 124 is reduced through the repeatedly performed RIE processing. Next, the substrate 101 having completed the RIE processing step is water-rinsed so as to complete the capacitor processing step.

Next, a capacitor portion, a transistor portion and a wiring portion are connected by a back-end process (wiring process) respectively. Although the details of a multilayer interconnection process are omitted, it includes a series of processes, such as insulating film formation (formation of a silicon dioxide film, a low-permittivity film, an organic film and the like by CVD, application, thermal process and the like, and formation of a barrier film such as the silicon nitride film), formation of connecting holes and trenches (oxide film RIE and the like), barrier film deposition (deposition of TiN, Ta, TaN and the like by sputtering, CVD and the like), wiring formation (Al sputtering, Cu sputtering, plating, annealing and the like) and wiring processing (Al RIE, Cu CMP and the like). After forming the multilayer interconnection, the silicon nitride film is formed as a passivation film, and a pad portion is opened.

The fatigue characteristics of the ferroelectric capacitor were evaluated. As a result of evaluating the fatigue characteristics on an array equivalent to area of 0.4 μm×0.4 μm, the amount of polarization did not change until 1×10¹² cycles, and the leakage current was also a low value of 10⁻⁷ A/cm² order on application of 2.5 V.

Other than the PZT film, the ferroelectric film 122 may be a SBT film, a SBT film added Nb, a BLT film, a PZT film added various additive elements, or a PLZT film added various additive elements. Other than the Ti film and Ir film, the lower electrode film 121 may be a Pt film, an Ru film, an RuO₂ film, an IrO₂ film, a film made of mixture of these materials, a laminated film including these films or the like. Noble metal oxide material constituting the upper electrode film 123 is not limited to IrO₂, but the same effects can be expected in the case of the noble metal oxides such as RuO₂, RhO₂, and PtOₓ (MOₓ-type conductive oxides), mixture of these materials, mixture with these materials as major components, mixture of these materials and Pt and the like.

### Second Embodiment

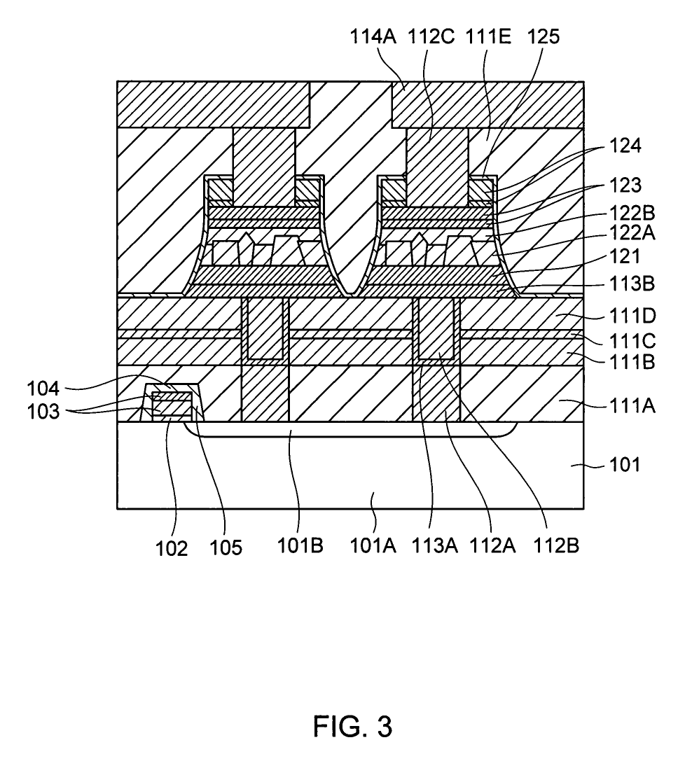

FIG. 3 is a cross-sectional view showing a semiconductor device according to a second embodiment. The semiconductor device shown in FIG. 3 will be described mainly focusing on its differences from the semiconductor device of the first embodiment.

The semiconductor device shown in FIG. 3 includes a substrate 101, a gate insulating film 102, a gate electrode film 103, a cap film 104 and a sidewall film 105. The substrate 101 is a silicon substrate. The substrate 101 has a diffusion layer 101A of a first conductivity type (P-type for example) and a source/drain diffusion layer 101B of a second conductivity type (N-type for example). The gate insulating film 102 is made of a silicon dioxide film, and is formed on the substrate 101. The gate electrode film 103 is made of laminated layers including a lower layer made of a polysilicon film and an upper layer made of a tungsten silicide (WSi₂) film, and is formed on the gate electrode film 102. The cap film 104 is made of a silicon nitride film, and is formed on the top surface of the gate. The sidewall film 105 is made of a silicon nitride film, and is formed on the side surface of the gate. A MOS-type field effect transistor is formed by these members and the like on the diffusion layer 101A (substrate 101).

The semiconductor device shown in FIG. 3 includes first, second, third and fourth interlayer insulating films 111A, 111B, 111C and 111D, first and second plug layers 112A and 112B, and first and second barrier layers 113A and 113B.

The semiconductor device shown in FIG. 3 includes a lower electrode film 121 for the capacitor, a first ferroelectric film 122A, a second ferroelectric film 122B, an upper electrode film 123 for the capacitor, a mask film 124 and a cover film 125. The lower electrode film 121 is made of an Ir (iridium) film, and is formed on the barrier layer 113B. The first ferroelectric film 122A is made of a first PZT film formed by in-situ crystallization of PZT by MOCVD method, and is formed on the lower electrode film 121. The second ferroelectric film 122B is made of a second PZT film, and is formed on the first ferroelectric film 122A. The upper electrode film 123 is made of laminated layers including a lower layer made of an SRO (SrRuO₃) film and an upper layer made of an IrOₓ (iridium oxide) film, and is formed on the second ferroelectric film 122B. The mask film 124 is made of laminated layers including a lower layer made of an aluminum oxide film and an upper layer made of a silicon dioxide film, and is formed on the upper electrode film 123. The cover film 125 is made of an aluminum oxide film, and is formed to cover the barrier layer 113B, lower electrode film 121, first ferroelectric film 122A, second ferroelectric film 122B, upper electrode film 123 and mask film 124. A stack-type ferroelectric capacitor is formed by these members and the like on the source/drain diffusion layer 101B (substrate 101).

The semiconductor device shown in FIG. 3 includes a fifth interlayer insulating film 111E, a third plug layer 112C and a first wiring layer 114A.

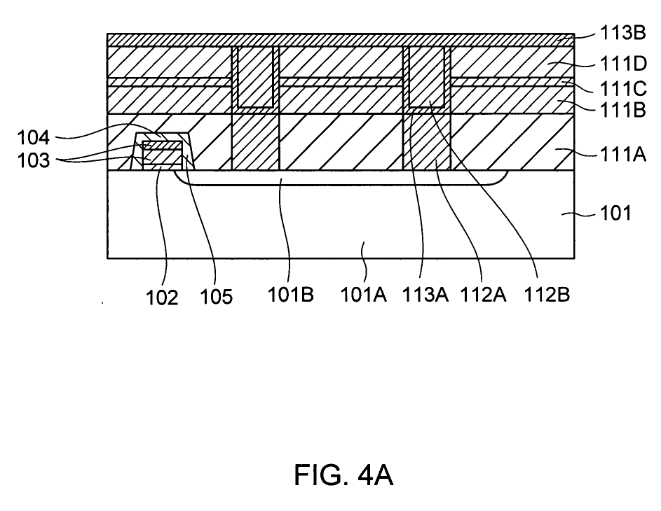

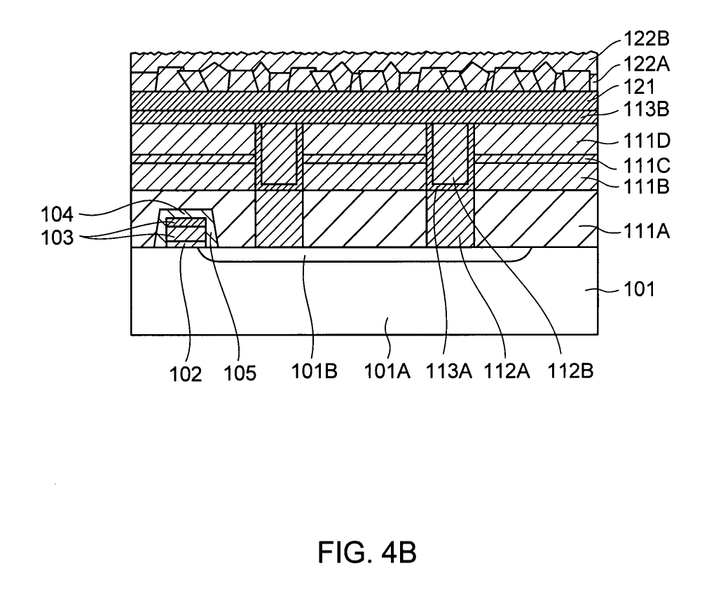

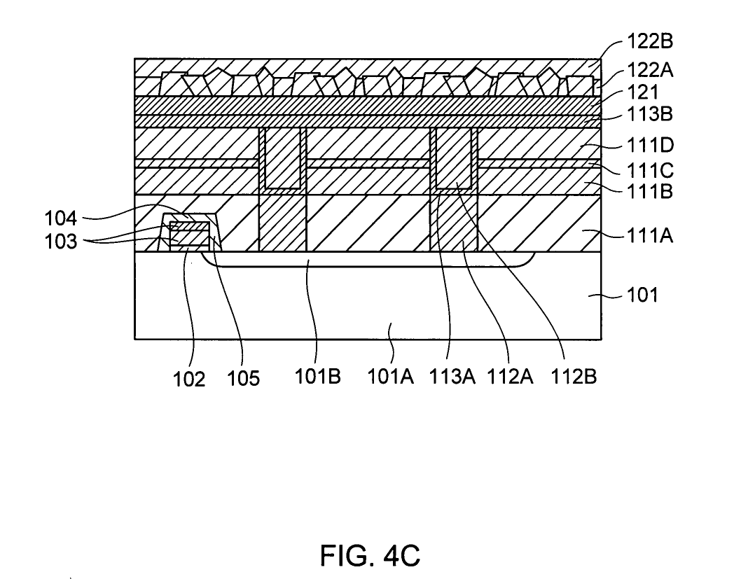

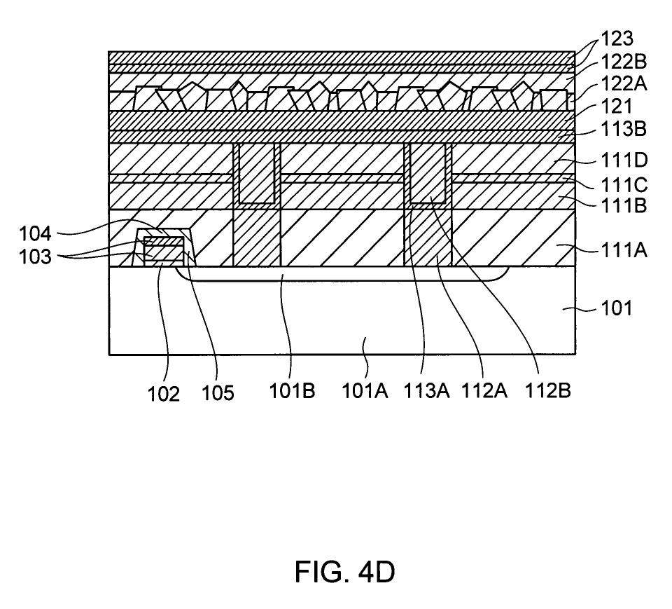

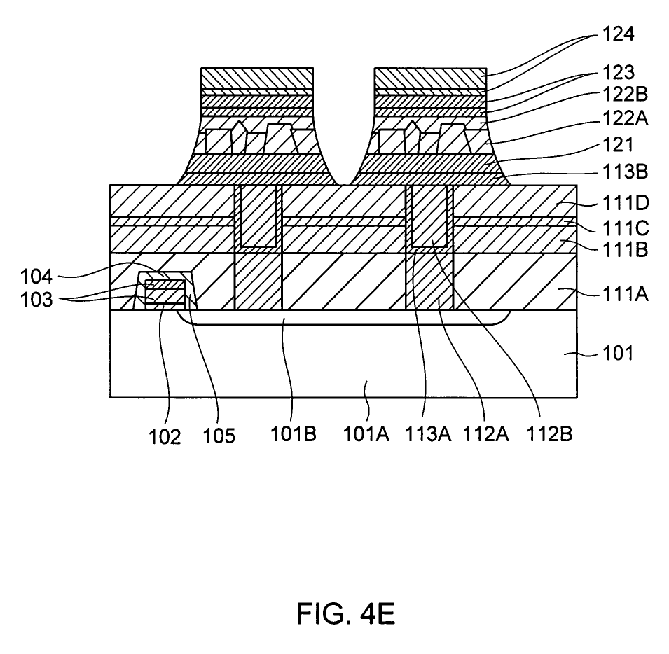

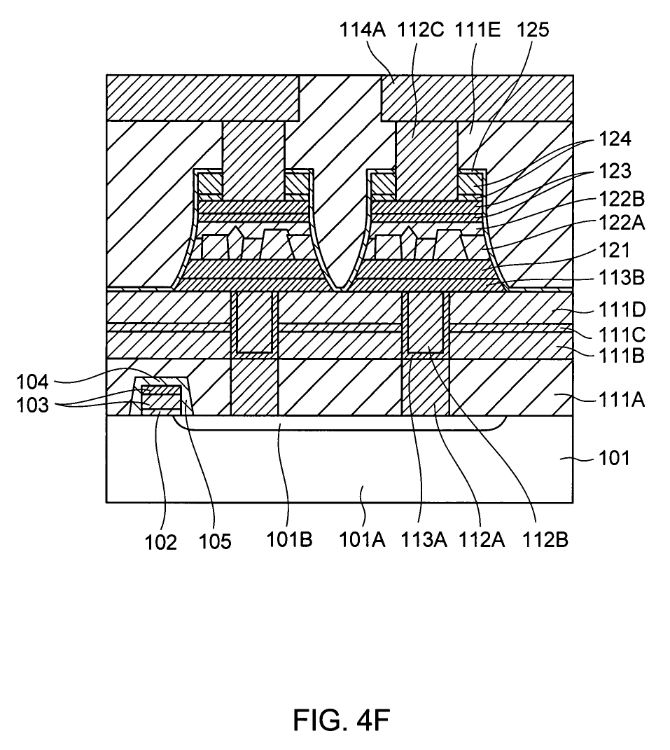

FIGS. 4A to 4F are cross-sectional views showing a manufacturing method of the semiconductor device according to the second embodiment. The manufacturing method shown in FIGS. 4A to 4F will be described mainly focusing on its differences from manufacturing method of the first embodiment.

First, as shown in FIG. 4A, a gate insulating film 102, a gate electrode film 103, a cap film 104, a sidewall film 105, interlayer insulating films 111A, 111B, 111C and 111D, plug layers 112A and 112B, and barrier layers 113A and 113B are formed on (or above) a substrate 101 by known methods. A diffusion layer 101A and a source/drain diffusion layer 101B are also formed by known methods.

Next, as shown in FIG. 4B, under the condition that the barrier layer 113B is deposited over the entire surface, an Ir film (lower electrode film 121) is formed on the barrier layer 113B by sputtering method or CVD method. The Ir film is deposited over the entire surface. Then, a first PZT film (first ferroelectric film 122A) is formed on the Ir film by in-situ crystallization of PZT by MOCVD method, using liquid material such that metallo-organic complex is melted in liquid. Thereby, irregularities due to the in-situ crystallization are formed on the surface of the first PZT film. The first PZT film is deposited over the entire surface. Then, a second PZT film (second ferroelectric film 122B) is formed on the first PZT film by sputtering method or CVD method. The second PZT film is deposited over the entire surface.

Next, as shown in FIG. 4C, a part of the second ferroelectric film 122B is removed through a planarizing process by CMP method (chemical mechanical polishing method) or etch-back method, to planarize the surface of the second ferroelectric film 122B.

Next, as shown in FIG. 4D, an SRO film (lower layer of upper electrode film 123) is formed on the second PZT film by sputtering method or CVD method. The SRO film is deposited over the entire surface. In the case where the SRO film is deposited in an amorphous state, an annealing process such as RTA is performed for crystallization of the SRO film. Then, an IrOₓ film (upper layer of the upper electrode film 123) is formed on the SRO film by sputtering method or CVD method. The IrOₓ film is deposited over the entire surface. In a reducing atmosphere such as hydrogen, the IrOₓ film works as a self-reduced buffer film, and shows high barrier properties against oxygen. Laminated films of the SRO film and IrOₓ film have advantages that the barrier properties against reducing gas are intensified, diffusion of Ir generated by reduction of the IrOₓ into the second PZT film is prevented, and the like. The IrOₓ film may undergo densification, crystallization and the like by a thermal process after deposition.

Next, an aluminum oxide film (lower layer of mask film 124) is formed on the IrOₓ film by sputtering method or CVD method. The aluminum oxide film is deposited over the entire surface. Then, a silicon dioxide film (upper layer of the mask film 124) is formed on the aluminum oxide film by sputtering method or CVD method. The silicon dioxide film is deposited over the entire surface. Then, as shown in FIG. 4E, the upper layer of the mask film 124 is processed by an etching by photolithography method and RIE method. Then, the lower layer of the mask film 124, the upper layer of the upper electrode film 123, the lower layer of the upper electrode film 123, the second ferroelectric film 122B, the first ferroelectric film 122A, the lower electrode film 121 and the barrier layer 113C are processed by an etching by RIE method.

Next, as shown in FIG. 4F, an aluminum oxide film (cover film 125) is formed on the mask film 124 by sputtering method or CVD method. The aluminum oxide film is deposited over the entire surface. Then, a silicon dioxide film (interlayer insulating film 111E) is formed on the aluminum oxide film by sputtering method or CVD method. The silicon dioxide film is deposited over the entire surface. Then, a part of the interlayer insulating film 111E is removed through a planarizing process by CMP method or etch-back method, to planarize the surface of the interlayer insulating film 111E. Then, the interlayer insulating film 111E, the cover film 125, the upper layer of the mask film 124 and the lower layer of the mask film 124 are processed by an etching by photolithography method and RIE method, to form a contact hole for embedding a plug layer 112C. Then, the interlayer insulating film 111E is processed by an etching by photolithography method and RIE method to form a trench for embedding a wiring layer 114A. Then, an annealing process (annealing conditions are oxygen atmosphere, 600 to 650° C., 30 to 60 minutes for example) is performed for recovery of the first PZT film from damage. If the damage is slight, this annealing process may be omitted. Then, member for forming the plug layer 112C and the wiring layer 114A are embedded in the contact hole and the trench by sputtering method or CVD method, to form the plug layer 112C and the wiring layer 114A of a dual damascene structure for connecting adjacent capacitors.

In the second embodiment, due to the in-situ crystallization, the surface of the first ferroelectric film 122A is irregular. However, due to the planarizing process, the surface of the second ferroelectric film 122B becomes flat, before the upper electrode film 123 is formed on the second ferroelectric film 122B. The maximum roughness of the irregularities (maximum of irregularity height) on the surface (top surface) of the second ferroelectric film 122B is smaller than that of the first ferroelectric film 122A. Therefore, the surface of the upper electrode film 123, that is, the interface between the upper electrode film 123 and its upper conductive layer (plug layer 112C), also becomes flat. This improves a joint between the upper electrode film 123 and its upper conductive layer (plug layer 112C). With regard to the flatness of the surface of the upper electrode film 123, it is desirable that the mean roughness of the irregularities (minute irregularities) on the surface of the upper electrode film 123 be 2.0 to 5.0 nm. Thereby, focus in lithography for the upper electrode film 123 becomes even. Further, the RIE processing of the capacitor becomes easier, so that the side surface of the capacitor can be processed to be even. Further, in terms of the electric characteristics and reliability, reducing damage from upward cannot be suffered easily, because coverage of the upper electrode becomes even. Further, it is also possible to suppress adverse influences such that, resulting from the occurrence of electrostatic concentration in a thin part of the ferroelectric film, a leakage current increases, withstand voltage reduces, fatigue characteristics deteriorate, and retention characteristics degrade. These preferred effects become particularly conspicuous when the thickness of the ferroelectric film becomes about 100 nm or less. In addition to these examples, the above-mentioned various adverse influences which the first ferroelectric film 122A formed by the in-situ crystallization has on the semiconductor device, are prevented by the planarizing process of the second ferroelectric film 122B, which improves the reliability of the semiconductor device and the yield of a product of the semiconductor device.

In the second embodiment, it is also possible, in the process shown in FIG. 4B, to form the second ferroelectric film 122B (second PZT film) on the first ferroelectric film 122A (first PZT film) by solution application method, solution dipping method, or bias sputtering method. If the second ferroelectric film 122B is deposited by solution application method, solution dipping method, or bias sputtering method, the second ferroelectric film 122B having a flat surface is deposited. Therefore, the planarizing process of the surface of the second ferroelectric film 122B is not required. That is, the process shown in FIG. 4C is not required. In the case where the planarizing process of the surface of the second ferroelectric film 122B is not performed, it is possible to prevent the occurrence of interface defects in the second ferroelectric film 122B due to the stress on the electrode interface by CMP, and prevent the adhesion of residues of CMP, so as to further suppress the deterioration of electric characteristics.

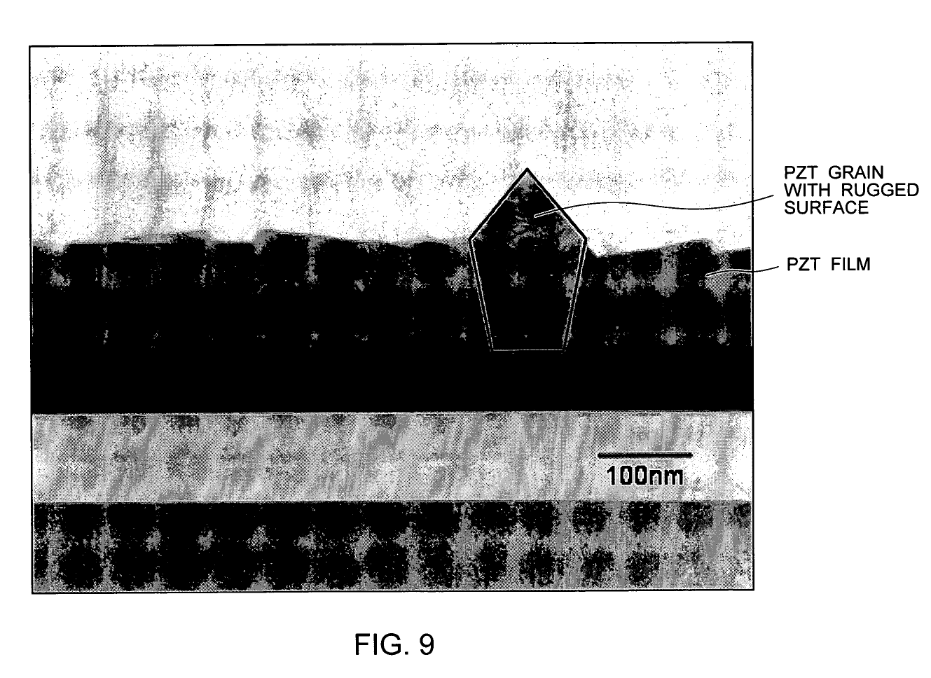

In the second embodiment, it is desirable that the maximum roughness of the irregularities on the surface of the first ferroelectric film 122A be 50 to 150 nm. Thereby, it is possible to buffer, by the irregularities on the interface between the first ferroelectric film and the second ferroelectric film, the lattice strain in the portion of the irregularities. It is also possible to reduce the leakage current generated through grain boundaries of the ferroelectric films. FIG. 9 shows a cross-sectional TEM image of a PZT film formed by in-situ crystallization of PZT by MOCVD method. The maximum roughness of the irregularities on the surface of the PZT film of FIG. 9 is about 80 nm. The maximum roughness of the irregularities on the surface of the PZT film is controllable by forming crystal grains as shown in FIG. 9, i.e., PZT grains with rugged surfaces. Area density of such crystal grains on the PZT film of FIG. 9 is 5 to 10 pieces/μm².

The following description will describe details and variations of the first ferroelectric film 122A.

The first ferroelectric film 122A is formed on the lower electrode film 121 by deposition with simultaneous crystallization using the MOCVD method. With regard to the MOCVD of the high-permittivity film and the ferroelectric film, vapor pressure of the material is generally low. Therefore, a solution vaporization method is widely used, which is the method for melting a metallo-organic complex material in an organic solvent, leading it into the carburetor in the solution state at normal temperature and forcibly vaporizing it. In comparison with the solid sublimation method, the solution vaporization method has advantages that it is easy to control a material supply, it is possible to increase deposition speed of the high-permittivity film and the ferroelectric film by increasing the material supplies, it is possible to monitor a remaining amount of the solution with a level sensor, and the like. The conditions of the MOCVD material are as follows: selective deposition should be easy, a high-purity film should be formable with little amounts of carbon and particles remaining in the film, the vapor pressure when it is a liquid should be high and its supply should be easy, it should be stable and storable without changing over time, its toxicity should be low enough to be safe to an environment and a human body, and the like. The first ferroelectric film 122A has the irregularities of which maximum roughness is 50 to 150 nm for example (80 nm for example) formed on its surface.

In the case of forming a PZT-type film as the first ferroelectric film 122A for example, Pb (dpm) 2, Zr (dpm) 4, Zr (O.t—C4H9) 4, Ti (O.i—C3H7) 4 and the like are used as the materials of the first ferroelectric film 122A. These materials are dissolved in THF (tetrahydrofuran) to be liquid materials. Subsequently, the liquid materials are gasified by pumping the inactive gases such as He and Ar as the carrier gases and spraying them to the carburetor. Subsequently, oxygen, dinitrogen monoxide and the like as the oxidizers are introduced into a chamber via the shower plate so as to deposit the first ferroelectric film 122A on the substrate 101 inside the chamber. A solution including Pb, Zr and Ti (cocktail source) may also be used as the material of the first ferroelectric film 122A. In this case, the temperature of the substrate 101 is set as 400 to 650° C., and the composition of the PZT film is controlled by controlling the gas supplies. For example, control is exerted so that the ratio of Pb becomes about 1.15 as the A/B ratio and the Zr/Ti ratio becomes 35/65 so as to deposit the PZT film. In this case, a deposition condition for crystallizing the PZT as the PZT film of the perovskite structure is applied. Here, the PZT is crystallized simultaneously with deposition (in-situ crystallized), which suppresses the defect formation on the interface between the lower electrode film 121 and the first ferroelectric film 122A, such as the positive ion excess, positive ion loss and oxygen loss. This leads to prevention of the deterioration of the ferroelectric characteristics, fatigue characteristics, imprint characteristics and retention characteristics. The thickness of the first ferroelectric film 122A is 70 to 150 nm here. On the other hand, the thickness of the first ferroelectric film 122A may be 50 nm or less. This is intended to reduce the size of the irregularities on the surface of an in-situ crystal film by reducing the thickness of the in-situ crystal film, and thereby utilize the in-situ crystal film of good characteristics while alleviating its adverse influences.

In the case of forming an SBT-type film as the first ferroelectric film 122A for example, Sr (dpm) 2/THF, Bi (C6H5) 3, Bi (CH3) 3, Bi (C2H5) 3, a solid material having phenyl and tolyl, Ta (OC2H5) 5, Nb (OC2H5) 5, Ta (C2H5) 5 and the like are used as the materials of the first ferroelectric film 122A. These liquid materials are gasified by pumping them with the inactive gases such as He and Ar as the carrier gases and spraying them to the carburetor. Or else, these liquid materials are introduced into the carburetor by the bubbling method. Subsequently, oxygen, dinitrogen monoxide and the like as the oxidizers are introduced into the chamber via the shower plate so as to deposit the first ferroelectric film 122A on the substrate 101 inside the chamber. A solution including Sr, Bi, Ta and Nb (cocktail source) may also be used as the material of the first ferroelectric film 122A. In this case, the temperature of the substrate 101 is set as 400 to 650° C., and the composition of the PZT film is controlled by controlling the gas supplies. In this case, a deposition condition for crystallizing the SBT or SBTN as the SBT film or SBTN film of a Bi layer compound structure is applied. Here, the SBT or SBTN is crystallized simultaneously with deposition (in-situ crystallized), which suppresses the defect formation on the interface between the lower electrode film 121 and the first ferroelectric film 122A, such as the positive ion excess, positive ion loss and oxygen loss. This leads to prevention of deterioration of the ferroelectric characteristics, fatigue characteristics, imprint characteristics and retention characteristics. The thickness of the first ferroelectric film 122A is 70 to 150 nm here. On the other hand, the thickness of the first ferroelectric film 122A may be 50 nm or less. This is intended to reduce the size of the irregularities on the surface of an in-situ crystal film by reducing the thickness of the in-situ crystal film, and thereby utilize the in-situ crystal film of good characteristics while alleviating its adverse influences.

With regard to specific examples of the first ferroelectric film 122A, a BIT-type film (Bi₄Ti₃O₁₂ or the like) can be named in addition to the PZT-type film (Pb (ZrₓTi₁₋ₓ) O₃ or the like) and the SBT-type film (SrBi₂Ta₂O₉ or the like).

The following description will describe details and variations of the second ferroelectric film 122B.

The second ferroelectric film 122B is formed on the surface of the first ferroelectric film 122A having the irregularities formed thereon by using the CSD (Chemical Solution Deposition) method such as sol-gel method. The second ferroelectric film 122B is desirably the ferroelectric film of the same composition as the first ferroelectric film 122A. However, it may also be a ferroelectric film of a different composition from the first ferroelectric film 122A. For example, in the case where the first ferroelectric film 122A is the PZT-type film, the second ferroelectric film 122B may be either a PZT-type film of a different composition (dopant, Zr/Ti ratio, Pb amount and the like) from the PZT-type film or a film of a type other than the PZT-type. In the case where the second ferroelectric film 122B has the same composition as the first ferroelectric film 122A, they have the same coercive force so as to have the effects that the leakage current generated due to the difference in the coercive force between the films is small and the breakdown voltage is high. In the case where the second ferroelectric film 122B is the ferroelectric film of a different composition from the first ferroelectric film 122A, it has the effects of allowing control to be exerted over a behavior of a domain wall on the interface portion of the first ferroelectric film and the second ferroelectric film, to change the coercive force and improve saturation characteristics so as to increase an amount of signals. In the case where, as an example of the second ferroelectric film 122B being the ferroelectric film of a different composition from the first ferroelectric film 122A, the lower layer film of the capacitor insulator is a Zr-rich film and the upper layer film is a Ti-rich film, such as when the first ferroelectric film 122A is a PZT-type film of which Zr/Ti is 60/40 while the second ferroelectric film 122B is a PZT-type film of which Zr/Ti is 40/60, it has the effects that the stress and strain exerted to the crystal film around the lower electrode interface can be reduced while having a large amount of polarization and a good squareness ratio as the characteristics of the Ti-rich film. In the case where the lower layer film of the capacitor insulator is a more Ti-rich film than the upper layer film, such as when the first ferroelectric film 122A is a PZT-type film of which Zr/Ti is 30/70 while the second ferroelectric film 122B is a PZT-type film of which Zr/Ti is 40/60, it has the effects that the PZT film can be more easily oriented in accordance with the orientation of the lower electrode (111 orientation for example) so as to increase the amount of polarization. In the case where the second ferroelectric film 122B is the PZT film, an amorphous film is deposited on the first ferroelectric film 122 by sol-gel method using a metal alkoxide solution such as lead acetate hydrate, Ti isopropoxide and Zr butoxide, by MOD method using a carboxylic acid metallic salt, or the like. After the amorphous film desiccates, crystallization annealing is performed in oxygen atmosphere by a process such as RTO. In this case, it is also possible to repeat the application, desiccation, and crystallization annealing process. It is possible to form the second ferroelectric film 122B by the solution application method such as sol-gel method or MOD method, solution dipping method, sputtering method such as bias sputtering method, CVD method such as mist CVD method, evaporation method or the like. In the case where the second ferroelectric film 122B is deposited by solution application method, solution dipping method, or bias sputtering method, the second ferroelectric film 122B having a flat surface is deposited. The mean roughness (Ra) of the irregularities on the surface of the second ferroelectric film 122B is about a few nm which is 5 nm or less. This value is smaller than the mean roughness of the irregularities on the surface of an MOCVD film.

### Third Embodiment

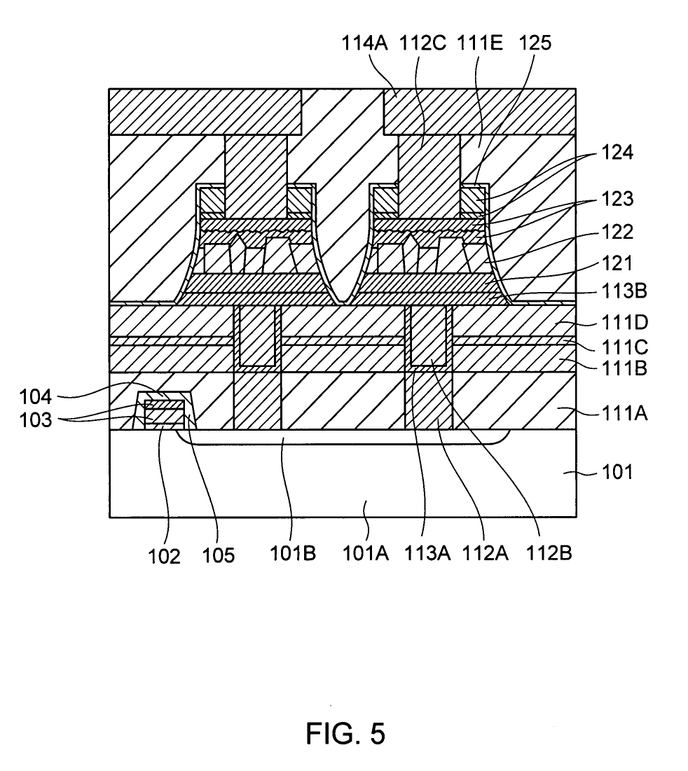

FIG. 5 is a cross-sectional view showing a semiconductor device according to a third embodiment. The semiconductor device shown in FIG. 5 will be described mainly focusing on its differences from the semiconductor device of the first embodiment.

The semiconductor device shown in FIG. 5 includes a substrate 101, a gate insulating film 102, a gate electrode film 103, a cap film 104 and a sidewall film 105. The substrate 101 is a silicon substrate. The substrate 101 has a diffusion layer 101A of a first conductivity type (P-type for example) and a source/drain diffusion layer 101B of a second conductivity type (N-type for example). The gate insulating film 102 is made of a silicon dioxide film, and is formed on the substrate 101. The gate electrode film 103 is made of laminated layers including a lower layer made of a polysilicon film and an upper layer made of a tungsten silicide (WSi₂) film, and is formed on the gate electrode film 102. The cap film 104 is made of a silicon nitride film, and is formed on the top surface of the gate. The sidewall film 105 is made of a silicon nitride film, and is formed on the side surface of the gate. A MOS-type field effect transistor is formed by these members and the like on the diffusion layer 101A (substrate 101).

The semiconductor device shown in FIG. 5 includes first, second, third and fourth interlayer insulating films 111A, 111B, 111C and 111D, first and second plug layers 112A and 112B, and first and second barrier layers 113A and 113B.

The semiconductor device shown in FIG. 5 includes a lower electrode film 121 for a capacitor, a ferroelectric film 122, an upper electrode film 123 for the capacitor, a mask film 124 and a cover film 125. The lower electrode film 121 is made of an Ir (iridium) film, and is formed on the barrier layer 113B. The ferroelectric film 122 is made of a PZT film formed by in-situ crystallization of PZT by MOCVD method, and is formed on the lower electrode film 121. The upper electrode film 123 is made of laminated layers including a lower layer made of an SRO (SrRuO₃) film and an upper layer made of an IrOₓ (iridium oxide) film, and is formed on the ferroelectric film 122. The mask film 124 is made of laminated layers including a lower layer made of an aluminum oxide film and an upper layer made of a silicon dioxide film, and is formed on the upper electrode film 123. The cover film 125 is made of an aluminum oxide film, and is formed to cover the barrier layer 113B, lower electrode film 121, ferroelectric film 122, upper electrode film 123 and mask film 124. A stack-type ferroelectric capacitor is formed by these members and the like on the source/drain diffusion layer 101B (substrate 101).

The semiconductor device shown in FIG. 5 includes a fifth interlayer insulating film 111E, a third plug layer 112C and a first wiring layer 114A.

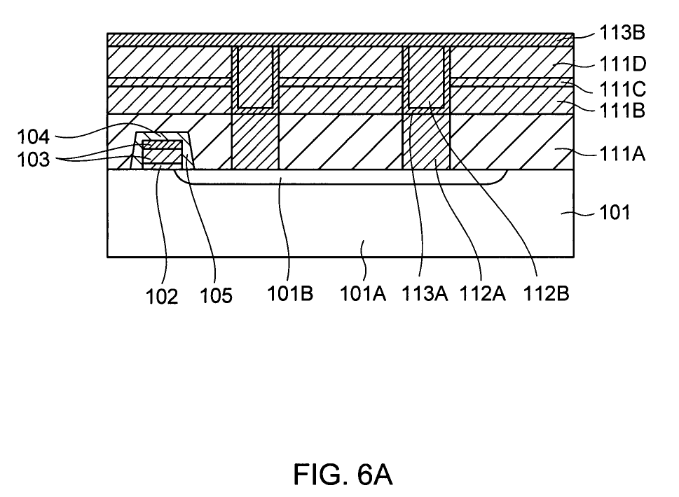

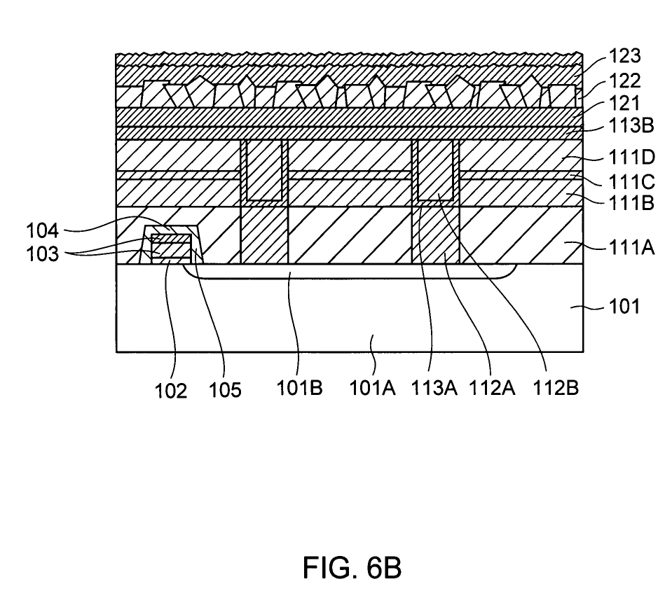

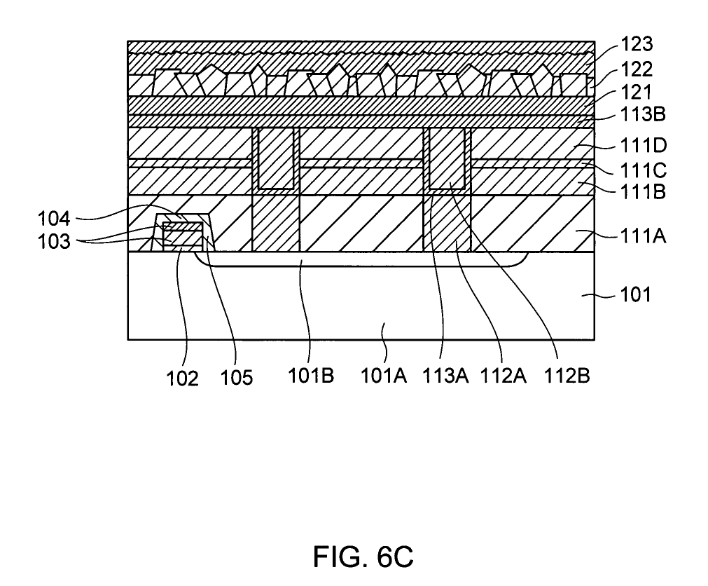

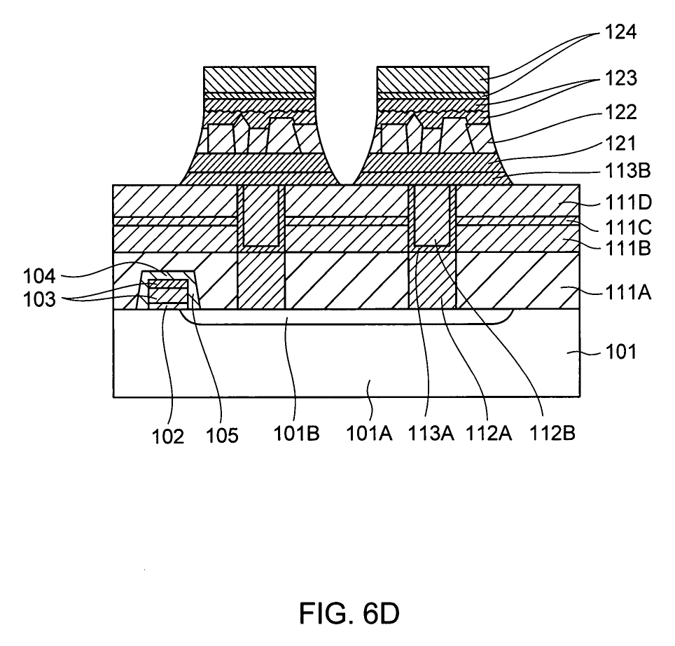

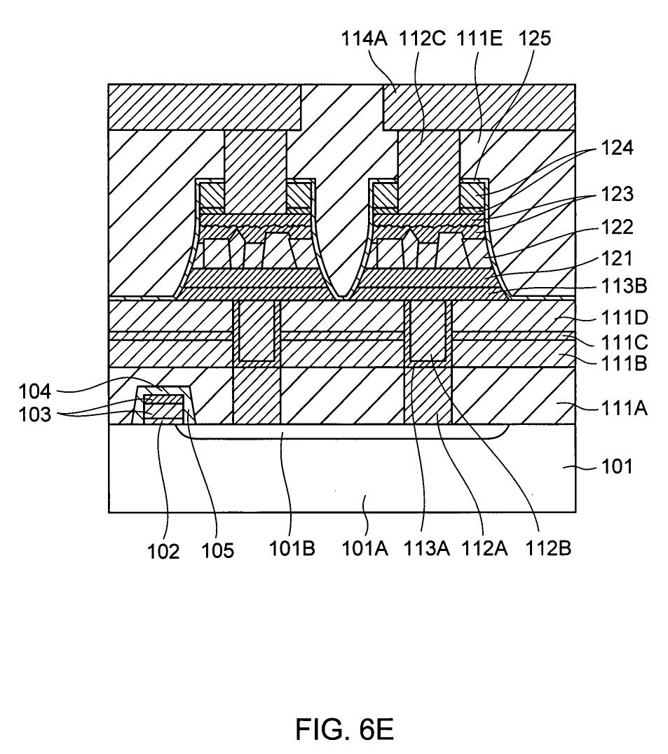

FIGS. 6A to 6E are cross-sectional views showing a manufacturing method of the semiconductor device according to the third embodiment. The manufacturing method shown in FIGS. 6A to 6E will be described mainly focusing on its differences from manufacturing method of the first embodiment.

First, as shown in FIG. 6A, a gate insulating film 102, a gate electrode film 103, a cap film 104, a sidewall film 105, interlayer insulating films 111A, 111B, 111C and 111D, plug layers 112A and 112B, and barrier layers 113A and 113B are formed on (or above) a substrate 101 by known methods. A diffusion layer 101A and a source/drain diffusion layer 101B are also formed by known methods.

Next, as shown in FIG. 6B, under the condition that the barrier layer 113B is deposited over the entire surface, an Ir film (lower electrode film 121) is formed on the barrier layer 113B by sputtering method or CVD method. The Ir film is deposited over the entire surface. Then, a PZT film (ferroelectric film 122) is formed on the Ir film by in-situ crystallization of PZT by MOCVD method, using liquid material such that metallo-organic complex is melted in liquid. Thereby, irregularities due to the in-situ crystallization are formed on the surface of the PZT film. The PZT film is deposited over the entire surface. Then, an SRO film (lower layer of upper electrode film 123) is formed on the PZT film by sputtering method or CVD method. The SRO film is deposited over the entire surface. In the case where the SRO is formed in an amorphous state, an annealing process such as RTA is performed for crystallization of the SRO film. Then, the IrOₓ film (upper layer of the upper electrode film 123) is formed on the SRO film by sputtering method or CVD method. The IrOₓ film is deposited over the entire surface. In a reducing atmosphere such as hydrogen, the IrOₓ film works as a self-reduced buffer film, and shows high barrier properties against oxygen. Laminated films of the SRO film and IrOₓ film have advantages that the barrier properties against reducing gas are intensified, diffusion of Ir generated by reduction of the IrOₓ into the PZT film is prevented, and the like. In the third embodiment, it is desirable that the maximum roughness of the irregularities on the surface of the ferroelectric film be 50 to 150 nm. This improves nucleation density of polarization domain on the interface between the ferroelectric film and its upper electrode, and improves the amount of signals for operation of the semiconductor device. Secondly, this increases effective area of the capacitor, and increases the amount of signals. Thirdly, this increases the amount of polarization by suppressing the relaxation of the stress on the ferroelectric film, and increases the amount of signals. These effects improve the reliability of the semiconductor device and the yield of a product of the semiconductor device.

Next, as shown in FIG. 6C, a part of the upper electrode film 123 (a part of the upper layer of the upper electrode film 123) is removed through a planarizing process by CMP method (chemical mechanical polishing method) or etch-back method, to planarize the surface of the upper electrode film 123 (the surface of the upper layer of the upper electrode film 123).

Next, an aluminum oxide film (lower layer of mask film 124) is formed on the IrOₓ film by sputtering method or CVD method. The aluminum oxide film is deposited over the entire surface. Then, a silicon dioxide film (upper layer of the mask film 124) is formed on the aluminum oxide film by sputtering method or CVD method. The silicon dioxide film is deposited over the entire surface. Then, as shown in FIG. 6D, the upper layer of the mask film 124 is processed by an etching by photolithography method and RIE method. Then, the lower layer of the mask film 124, the upper layer of the upper electrode film 123, the lower layer of the upper electrode film 123, the ferroelectric film 122, the lower electrode film 121 and the barrier layer 113C are processed by an etching by RIE method.

Next, as shown in FIG. 6E, an aluminum oxide film (cover film 125) is formed on the mask film 124 by sputtering method or CVD method. The aluminum oxide film is deposited over the entire surface. Then, a silicon dioxide film (interlayer insulating film 111E) is formed on the aluminum oxide film by sputtering method or CVD method. The silicon dioxide film is deposited over the entire surface. Then, a part of the interlayer insulating film 111E is removed through a planarizing process by CMP method or etch-back method, to planarize the surface of the interlayer insulating film 111E. Then, the interlayer insulating film 111E, the cover film 125, the upper layer of the mask film 124 and the lower layer of the mask film 124 are processed by an etching by photolithography method and RIE method, to form a contact hole for embedding a plug layer 112C. Then, the interlayer insulating film 111E is processed by an etching by photolithography method and RIE method, to form a trench for embedding a wiring layer 114A. Then, an annealing process (annealing conditions are oxygen atmosphere, 600 to 650° C., 30 to 60 minutes for example) is performed for recovery of the PZT film from damage. Then, member for forming the plug layer 112C and the wiring layer 114A is embedded in the contact hole and the trench by sputtering method or CVD method, to form the plug layer 112C and the wiring layer 114A of a dual damascene structure for connecting adjacent capacitors.

In the third embodiment, due to the in-situ crystallization, the surface of the ferroelectric film 122 is irregular. However, due to the planarizing process, the surface of the upper electrode film 123 becomes flat. The maximum roughness of the irregularities (maximum of irregularity height) on the surface (top surface) of the upper electrode film 123 is smaller than that of the ferroelectric film 122. Due to the planarizing process, the interface between the upper electrode film 123 and its upper conductive layer (plug layer 112C) becomes flat. This improves a joint between the upper electrode film 123 and its upper conductive layer (plug layer 112C). With regard to the flatness of the surface of the upper electrode film 123, it is desirable that the mean roughness of the irregularities (minute irregularities) on the surface of the upper electrode film 123 be 2.0 to 5.0 nm. Thereby, focus in lithography for the upper electrode film 123 becomes even. Further, the RIE processing of the capacitor becomes easier, so that the side surface of the capacitor can be processed to be even. Further, in terms of the electric characteristics and reliability, reducing damage from upward cannot be suffered easily, because coverage of the upper electrode becomes even. In addition to these examples, the above-mentioned various adverse influences which the ferroelectric film 122 formed by the in-situ crystallization has on the semiconductor device, are prevented by the planarizing process of the upper electrode film 123, which improves the reliability of the semiconductor device and the yield of a product of the semiconductor device. It is also possible, instead of performing the planarizing process to the upper layer of the upper electrode film 123, to perform the planarizing process to the lower layer or an intermediate layer (in the case where the intermediate layer exists) of the upper electrode film 123.

In the third embodiment, it is also possible, in the process shown in FIG. 6B, to form the upper layer (IrOₓ film) of the upper electrode film 123 by solution application method, solution dipping method, or bias sputtering method. If the upper layer of the upper electrode film 123 is deposited by solution application method, solution dipping method, or bias sputtering method, the upper layer (of the upper electrode film 123) having a flat surface is deposited. Therefore, the planarizing process of the surface of the upper layer of the upper electrode film 123 is not required. That is, the process shown in FIG. 6C is not required. It is also possible, instead of depositing the upper layer of the upper electrode film 123 by solution application method, solution dipping method, or bias sputtering method, to deposit the lower layer (SRO film) or an intermediate layer (in the case where the intermediate layer exists) of the upper electrode film 123 by solution application method, solution dipping method, or bias sputtering method.

In the third embodiment, it is desirable that the maximum roughness of the irregularities on the surface of the ferroelectric film 122 be 50 to 150 nm. This improves nucleation density of polarization domain on the interface between the ferroelectric film 122 and its upper electrode (upper electrode film 123), and improves the amount of signals for operation of the semiconductor device. Secondly, this increases effective area of the capacitor, and increases the amount of signals. Thirdly, this increases the amount of polarization by suppressing the relaxation of the stress on the ferroelectric film 122, and increases the amount of signals. These effects improve the reliability of the semiconductor device and the yield of a product of the semiconductor device. FIG. 9 shows a cross-sectional TEM image of a PZT film formed by in-situ crystallization of PZT by MOCVD method. The maximum roughness of the irregularities on the surface of the PZT film of FIG. 9 is about 80 nm. The maximum roughness of the irregularities on the surface of the PZT film is controllable by forming crystal grains as shown in FIG. 9, i.e., PZT grains with rugged surfaces. Area density of such crystal grains on the PZT film of FIG. 9 is 5 to 10 pieces/μm².

The following description will describe details and variations of the upper electrode film 123.

A noble metal film made of a noble metal such as Pt or Ir is used as the upper electrode film 123 in many cases. However, it is also possible to use, as the upper electrode film 123, a conductive oxide film made of a conductive oxide having the perovskite structure of an ABOₓ type (A and B are metal elements, O is an oxygen element, and x is a natural number), a conductive oxide film made of a conductive oxide of an MOₓ type (M is a metal element, O is an oxygen element, and x is a natural number), or a laminated film including these films, in order to suppress the damage to the capacitor in the CVD-processing of the mask film 124 and the interlayer insulating film 111E, in the RIE-processing of the capacitor, and in the sintering-processing in a forming gas. Many of the conductive oxides of the ABOₓ type have the perovskite structure. With regard to representative examples of the metal element A, alkaline-earth metals such as Pb, Ba, Sr and Ca can be named. With regard to representative examples of the metal element B, the metal elements such as Ti, Nb, Mg, Zr, Zn, Ta, W and Mn can be named. The “x” of ABOₓ is typically “3,” which is changeable depending on whether the oxygen is in excess or in loss. With regard to specific examples of the conductive oxides of the ABOₓ type, the SrRuO₃ (SRO), LaNiO₃ (LNO), (La, Sr) CoO₃ and YBCO (superconductor) can be named. With regard to a specific example of the upper electrode film 123, a laminated film of SRO and IrOₓ can be named. Defects such as oxygen losses on the interface between the ferroelectric film 122 and the upper electrode film 123, significantly influences tolerance of reducing process damage, deterioration of fatigue characteristic, deterioration of retention and deterioration of imprint, in a capacitor manufacturing process thereafter.

It is possible to form the upper layer of the upper electrode film 123 by solution application method such as sol-gel method or MOD method, solution dipping method, sputtering method such as bias sputtering method, CVD method such as mist CVD method, evaporation method or the like. In the case where the upper layer of the upper electrode film 123 is deposited by solution application method, solution dipping method, or bias sputtering method, the upper layer of the upper electrode film 123 having a flat surface is deposited. The mean roughness (Ra) of the irregularities on the surface of the upper layer of the upper electrode film 123 is about a few nm which is 5 nm or less. This value is smaller than the mean roughness of the irregularities on the surface of an MOCVD film. This also applies to the lower layer or the intermediate layer (in the case where the intermediate layer exists) of the upper electrode film 123.

### Fourth Embodiment

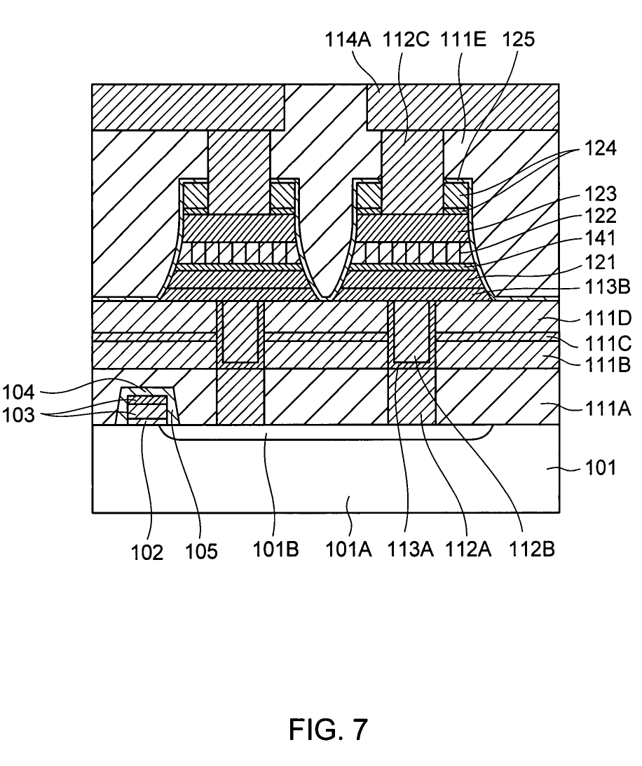

FIG. 7 is a cross-sectional view showing a semiconductor device according to a fourth embodiment. The semiconductor device shown in FIG. 7 will be described mainly focusing on its differences from the semiconductor device of the first embodiment.

The semiconductor device shown in FIG. 7 includes a substrate 101, a gate insulating film 102, a gate electrode film 103, a cap film 104 and a sidewall film 105. The substrate 101 is a silicon substrate. The substrate 101 has a diffusion layer 101A of a first conductivity type (P-type for example) and a source/drain diffusion layer 101B of a second conductivity type (N-type for example). The gate insulating film 102 is made of a silicon dioxide film, and is formed on the substrate 101. The gate electrode film 103 is made of laminated layers including a lower layer made of a polysilicon film and an upper layer made of a tungsten silicide (WSi₂) film, and is formed on the gate electrode film 102. The cap film 104 is made of a silicon nitride film, and is formed on the top surface of the gate. The sidewall film 105 is made of a silicon nitride film, and is formed on the side surface of the gate. A MOS-type field effect transistor is formed by these members and the like on the diffusion layer 101A (substrate 101).

The semiconductor device shown in FIG. 7 includes first, second, third and fourth interlayer insulating films 111A, 111B, 111C and 111D, first and second plug layers 112A and 112B, and first and second barrier layers 113A and 113B.

The semiconductor device shown in FIG. 7 includes a lower electrode film 121 for a capacitor, a ground film 141, a ferroelectric film 122, an upper electrode film 123 for the capacitor, a mask film 124 and a cover film 125. The lower electrode film 121 is made of an Ir (iridium) film, and is formed on the barrier layer 113B. The ground film 141, which is used as a ground of the ferroelectric film 122, is made of an oriented film (e.g. a conductive film) oriented in a specific direction or a crystal film (e.g. a ferroelectric film) formed by crystallization of amorphous, and is formed on the lower electrode film 121. The ferroelectric film 122 is made of a PZT film formed by in-situ crystallization of PZT by MOCVD method, and is formed on the ground film 141. The upper electrode film 123 is made of an IrOₓ (iridium oxide) film, and is formed on the ferroelectric film 122. The mask film 124 is made of laminated layers including a lower layer made of an aluminum oxide film and an upper layer made of a silicon dioxide film, and is formed on the upper electrode film 123. The cover film 125 is made of an aluminum oxide film, and is formed to cover the barrier layer 113B, lower electrode film 121, ground film 141, ferroelectric film 122, upper electrode film 123 and mask film 124. A stack-type ferroelectric capacitor is formed by these members and the like on the source/drain diffusion layer 101B (substrate 101).

The semiconductor device shown in FIG. 7 includes a fifth interlayer insulating film 111E, a third plug layer 112C and a first wiring layer 114A.

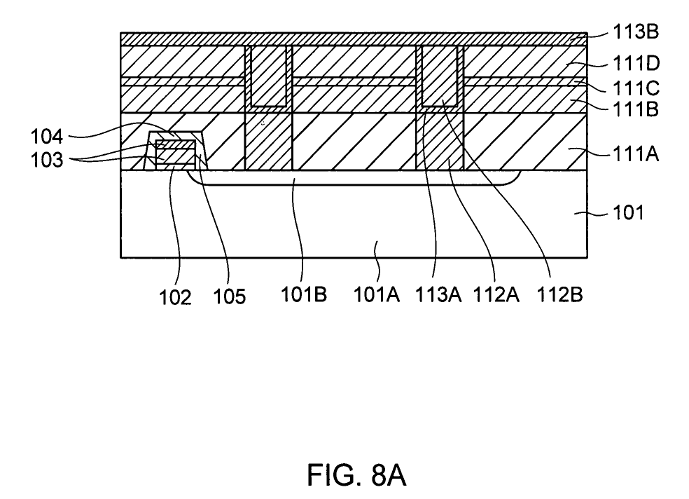

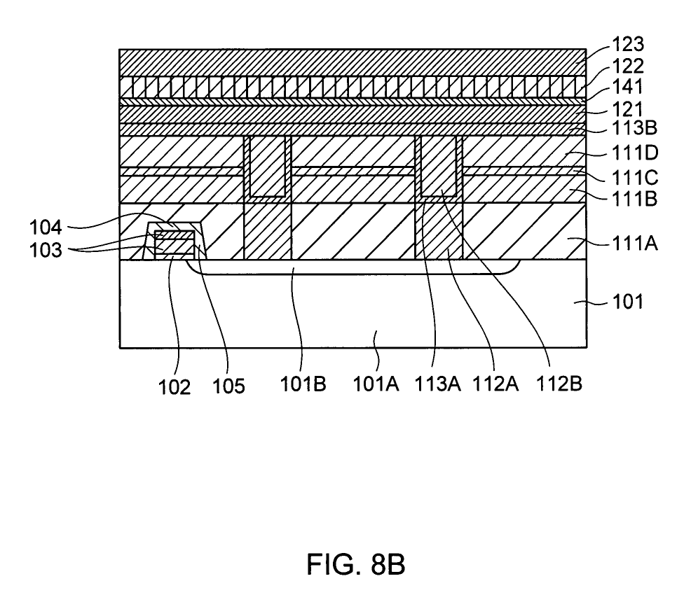

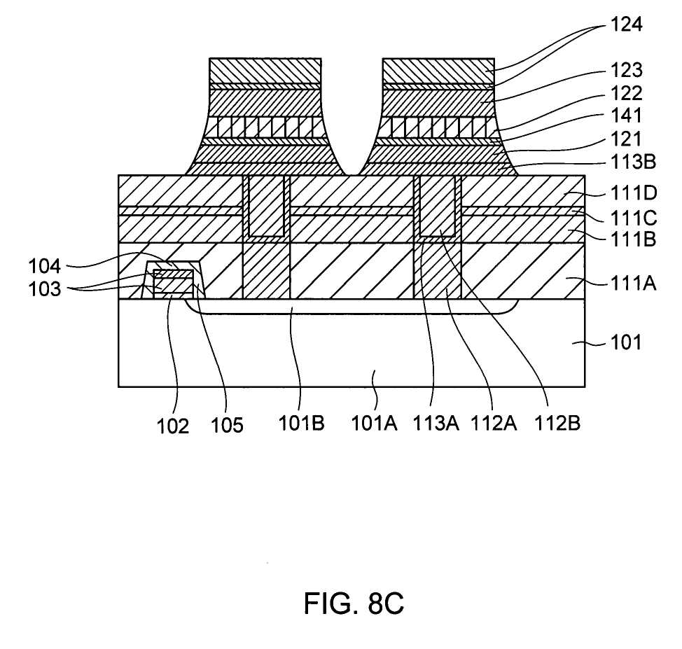

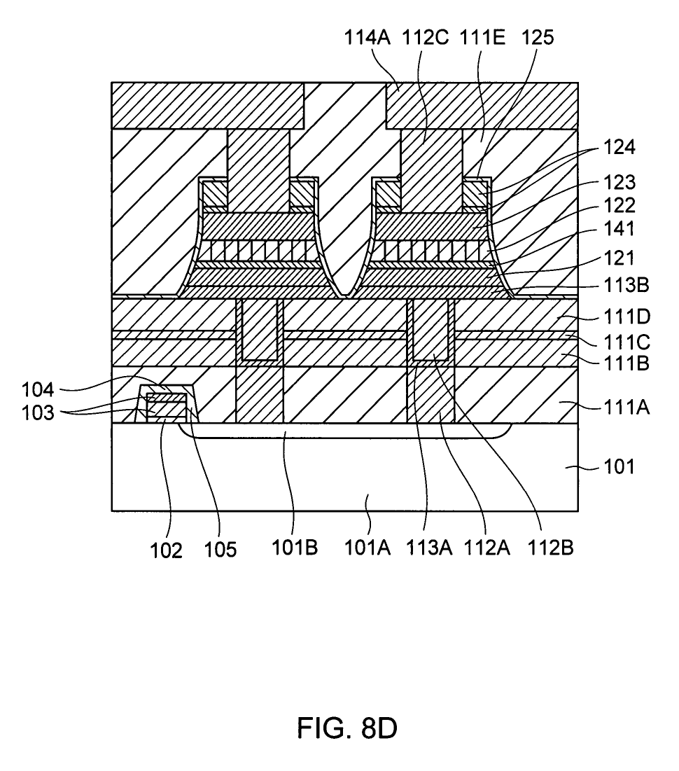

FIGS. 8A to 8D are cross-sectional views showing a manufacturing method of the semiconductor device according to the fourth embodiment. The manufacturing method shown in FIGS. 8A to 8D will be described mainly focusing on its differences from manufacturing method of the first embodiment.

First, as shown in FIG. 8A, a gate insulating film 102, a gate electrode film 103, a cap film 104, a sidewall film 105, interlayer insulating films 111A, 111B, 111C and 111D, plug layers 112A and 112B, and barrier layers 113A and 113B are formed on (or above) a substrate 101 by known methods. A diffusion layer 101A and a source/drain diffusion layer 101B are also formed by known methods.

Next, as shown in FIG. 8B, under the condition that the barrier layer 113B is deposited over the entire surface, an Ir film (lower electrode film 121) is formed on the barrier layer 113B by sputtering method or CVD method. The Ir film is deposited over the entire surface. Then, the ground film 141, which is used as a ground of a ferroelectric film 122, is formed on the Ir film. The ground film 141 is deposited over the entire surface. The ground film 141 may be an oriented film (e.g. a conductive film) oriented in a specific direction or a crystal film (e.g. a ferroelectric film) formed by crystallization of amorphous. For example, a PZT-type film, a SRO/PZT laminated film or the like is formed by sputtering method or sol-gel method, to form a perovskite film oriented to a (111) plane on the Ir film. As a matter of course, it may be another conductive perovskite film or an MOₓ type conductive film. Then, a PZT film (the ferroelectric film 122) is formed on the ground film 141 by in-situ crystallization of PZT by MOCVD method, using liquid material such that metallo-organic complex melted is melted in liquid. The PZT film is deposited over the entire surface. Then, an IrOₓ film (upper electrode film 123) is formed on the PZT film by sputtering method or CVD method. The IrOₓ film is deposited over the entire surface. In a reducing atmosphere such as hydrogen, the IrOₓ film works as a self-reduced buffer film, and shows high barrier properties against oxygen. The IrOₓ film has advantages that the barrier properties against reducing gas are intensified, diffusion of Ir generated by reduction of the IrOₓ into the PZT film is prevented, and the like.

Next, an aluminum oxide film (lower layer of mask film 124) is formed on the IrOₓ film by sputtering method or CVD method. The aluminum oxide film is deposited over the entire surface. Then, a silicon dioxide film (upper layer of the mask film 124) is formed on the aluminum oxide film by sputtering method or CVD method. The silicon dioxide film is deposited over the entire surface. Then, as shown in FIG. 8C, the upper layer of the mask film 124 is processed by an etching by photolithography method and RIE method. Then, the lower layer of the mask film 124, the upper electrode film 123, the ferroelectric film 122, the ground film 141, the lower electrode film 121 and the barrier layer 113C are processed by an etching by RIE method.

Next, as shown in FIG. 8D, an aluminum oxide film (cover film 125) is formed on the mask film 124 by sputtering method or CVD method. The aluminum oxide film is deposited over the entire surface. Then, a silicon dioxide film (interlayer insulating film 111E) is formed on the aluminum oxide film by sputtering method or CVD method. The silicon dioxide film is deposited over the entire surface. Then, a part of the interlayer insulating film 111E is removed through a planarizing process by CMP method or etch-back method, to planarize the surface of the interlayer insulating film 111E. Then, the interlayer insulating film 111E, the cover film 125, the upper layer of the mask film 124 and the lower layer of the mask film 124 are processed by an etching by photolithography method and RIE method, to form a contact hole for embedding a plug layer 112C. Then, the interlayer insulating film 111E is processed by an etching by photolithography method and RIE method, to form a trench for embedding a wiring layer 114A. Then, an annealing process (annealing conditions are oxygen atmosphere, 600 to 650° C., 30 to 60 minutes for example) is performed for recovery of the PZT film from damage. Then, member for forming the plug layer 112C and the wiring layer 114A is embedded in the contact hole and the trench by sputtering method or CVD method, to form the plug layer 112C and the wiring layer 114A of a dual damascene structure for connecting adjacent capacitors.

In the fourth embodiment, the ferroelectric film 122 is formed on the ground film 141 by in-situ crystallization. In the case where the ground film 141 is made of an oriented film (e.g. a conductive film) oriented in a specific direction, if the ferroelectric film 122 is formed on the ground film 141 by in-situ crystallization, the ferroelectric film 122 oriented in the specific direction is formed. For example, if the ground film 141 is oriented in a <111> direction, the ferroelectric film 122 oriented in the <111> direction is formed. In the case where the lower electrode film is a conductive film containing Ir and Pt, it is easy to form the ground film 141 oriented in the <111> direction. Thereby, crystal grains forming the ferroelectric film 122 become even, and the surface of the ferroelectric film 122 becomes flat. In the case where the ground film 141 is made of a crystal film (e.g. a ferroelectric film) formed by crystallization of amorphous, if the ferroelectric film 122 is formed on the ground film 141 by in-situ crystallization, the ferroelectric film 122 having a flat surface is formed due to the effects of the crystal film. Therefore, in the fourth embodiment, planarizing processes of the surfaces of the ferroelectric film 122 and the upper electrode film 123 are not required.

In the fourth embodiment, the upper electrode film 123 is formed on the ferroelectric film 122. Therefore, the surface of the upper electrode film 123, that is, the interface between the upper electrode film 123 and its upper conductive layer (plug layer 112C), also becomes flat. This improves a joint between the upper electrode film 123 and its upper conductive layer (plug layer 112C). With regard to the flatness of the surface of the upper electrode film 123, it is desirable that the mean roughness of the irregularities (minute irregularities) on the surface of the upper electrode film 123 be 2.0 to 5.0 nm. Thereby, focus in lithography for the upper electrode film 123 becomes even. Further, the RIE processing of the capacitor becomes easier, so that the side surface of the capacitor can be processed to be even. Further, in terms of the electric characteristics and reliability, reducing damage from upward cannot be suffered easily, because coverage of the upper electrode becomes even. Further, it is also possible to suppress adverse influences such that, resulting from the occurrence of electrostatic concentration in a thin part of the ferroelectric film, a leakage current increases, withstand voltage reduces, fatigue characteristics deteriorate, and retention characteristics degrade. These preferred effects become particularly conspicuous when the thickness of the ferroelectric film becomes about 100 nm or less. In addition to these examples, the above-mentioned various adverse influences which the ferroelectric film 122 formed by the in-situ crystallization has on the semiconductor device, are prevented by the ground film 141, which improves the reliability of the semiconductor device and the yield of a product of the semiconductor device.

The following description will describe details and variations of the ground film 141.

Conductive oxide films of the perovskite structure containing Sr (strontium) can be named as examples of the ground film 141. For example, those which can be the ground film 141 are an SrRuO₃ film, an Sr (Ru, Ti) O₃ film, an SrTiO₃ film doped Nb or Lb, a laminated film of SrTiO₃ film and PZT film, a laminated film of SRO film and PZT film, a mixed film of SRO and PZT and the like.

A method of forming the ground film 141 made of a mixed film of SRO and PZT is as follows. First, an SRO amorphous film of which thickness is 20 nm or less is formed on the Ir film by DC magnetron sputtering by using a target made of an SRO ceramic, and an RTO thermal process of the substrate 101 is performed. If the SRO is a thin film, the SRO does not have a perovskite crystal structure but remains in an amorphous state. As a matter of course, the RTO thermal process may not be performed. With regard to sputtering conditions of the SRO film, sputtering deposition is performed by input of 0.5 to 1.0 kW to a target of 300 mm, using a mixture gas of Ar/O₂ (flow rate of O₂ is 700% or less), and with a pressure of about 0.5 to 1.0 Pa. Next, a PZT amorphous thin film of which thickness is 5 to 50 nm is formed on the SRO film. A PZT ceramic target is used for PZT sputtering deposition. With regard to sputtering conditions of the PZT film, sputtering deposition is performed by input of 1.0 to 2.0 kW, using an Ar sputtering gas, and under a pressure of 0.5 to 2.0 Pa. Since the temperature of the substrate 101 is the room temperature, the PZT film to be formed becomes the PZT film in an amorphous state. After forming the SRO film and the PZT film, the RTO thermal process of the substrate 101 is performed on thermal process conditions of 650° C., in oxygen, and 1 minute, so as to crystallize the SRO and PZT. Thereby, a conductive film of a perovskite structure containing the SRO and PZT (ground film 141) is formed on the lower electrode film 121. The ground film 141 may also be the film which is oriented in a specific direction and formed by crystallization of amorphous.

The following description will describe details and variations of the ferroelectric film 122.

The ferroelectric film 122 is formed on the ground film 141 by deposition with simultaneous crystallization using the MOCVD method. With regard to the MOCVD of a high-permittivity film and the ferroelectric film, vapor pressure of the material is generally low. Therefore, a solution vaporization method is widely used, which is the method for melting a metallo-organic complex material in an organic solvent, leading it into a carburetor in a solution state at normal temperature and forcibly vaporizing it. In comparison with a solid sublimation method, the solution vaporization method has advantages that it is easy to control a material supply, it is possible to increase deposition speed of the high-permittivity film and the ferroelectric film by increasing the material supplies, it is possible to monitor a remaining amount of the solution with a level sensor, and the like. The conditions of an MOCVD material are as follows: selective deposition should be easy, a high-purity film should be formable with little amounts of carbon and particles remaining in the film, vapor pressure when it is a liquid should be high and its supply should be easy, it should be stable and storable without changing over time, its toxicity should be low enough to be safe to an environment and a human body, and the like. The mean roughness (Ra) of the irregularities on the surface of the ferroelectric film 122 is 5 nm or less. This is supposedly because the orientation of the ground film 141 is uniformly in the <111> direction and so the orientation of the MOCVD film becomes uniformly in the <111> direction, so that the forms of PZT crystal grains of the MOCVD film become uniform.

### Fifth Embodiment

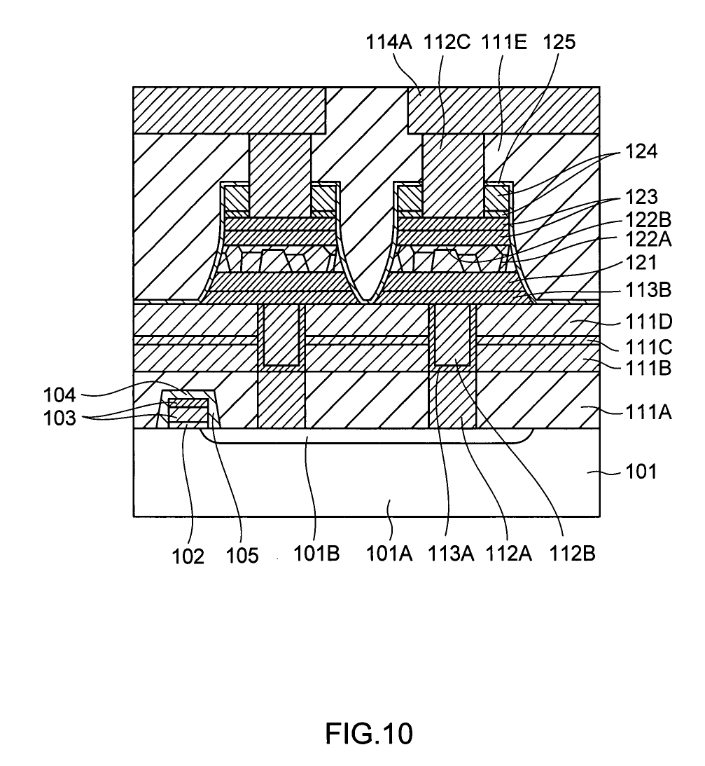

FIG. 10 is a cross-sectional view showing a semiconductor device according to a fifth embodiment. The semiconductor device shown in FIG. 10 will be described mainly focusing on its differences from the semiconductor device of the first embodiment.

The semiconductor device shown in FIG. 10 includes a substrate 101, a gate insulating film 102, a gate electrode film 103, a cap film 104 and a sidewall film 105. The substrate 101 is a silicon substrate. The substrate 101 has a diffusion layer 101A of a first conductivity type (P-type for example) and a source/drain diffusion layer 101B of a second conductivity type (N-type for example). The gate insulating film 102 is made of a silicon dioxide film, and is formed on the substrate 101. The gate electrode film 103 is made of laminated layers including a lower layer made of a polysilicon film and an upper layer made of a tungsten silicide (WSi₂) film, and is formed on the gate electrode film 102. The cap film 104 is made of a silicon nitride film, and is formed on the top surface of the gate. The sidewall film 105 is made of a silicon nitride film, and is formed on the side surface of the gate. A MOS-type field effect transistor is formed by these members and the like on the diffusion layer 101A (substrate 101).

The semiconductor device shown in FIG. 10 includes first, second, third and fourth interlayer insulating films 111A, 111B, 111C and 111D, first and second plug layers 112A and 112B, and first and second barrier layers 113A and 113B.

The semiconductor device shown in FIG. 10 includes a lower electrode film 121 for a capacitor, a first ferroelectric film 122A, a second ferroelectric film 122B, an upper electrode film 123 for the capacitor, a mask film 124 and a cover film 125. The lower electrode film 121 is made of an Ir (iridium) film, and is formed on the barrier layer 113B. The first ferroelectric film 122A is made of a first PZT film formed by in-situ crystallization of PZT by MOCVD method, and is formed on the lower electrode film 121. The second ferroelectric film 122B is made of a second PZT film, and is formed on the first ferroelectric film 122A. The upper electrode film 123 is made of laminated layers including a lower layer made of an SRO (SrRuO₃) film and an upper layer made of an IrOₓ (iridium oxide) film, and is formed on the second ferroelectric film 122B. The mask film 124 is made of laminated layers including a lower layer made of an aluminum oxide film and an upper layer made of a silicon dioxide film, and is formed on the upper electrode film 123. The cover film 125 is made of an aluminum oxide film, and is formed to cover the barrier layer 113B, lower electrode film 121, first ferroelectric film 122A, second ferroelectric film 122B, upper electrode film 123 and mask film 124. A stack-type ferroelectric capacitor is formed by these members and the like on the source/drain diffusion layer 101B (substrate 101).

The semiconductor device shown in FIG. 10 includes a fifth interlayer insulating film 111E, a third plug layer 112C and a first wiring layer 114A.

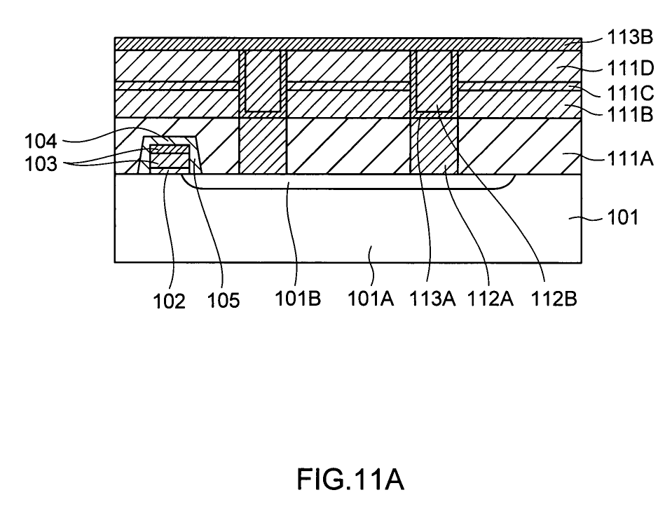

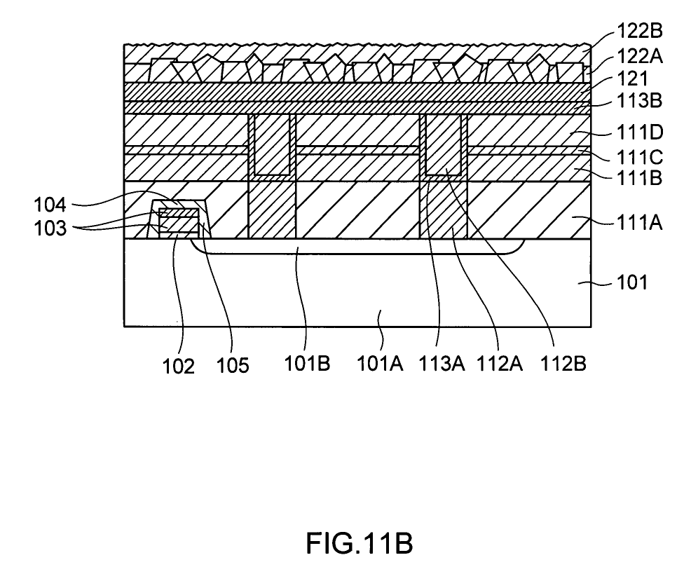

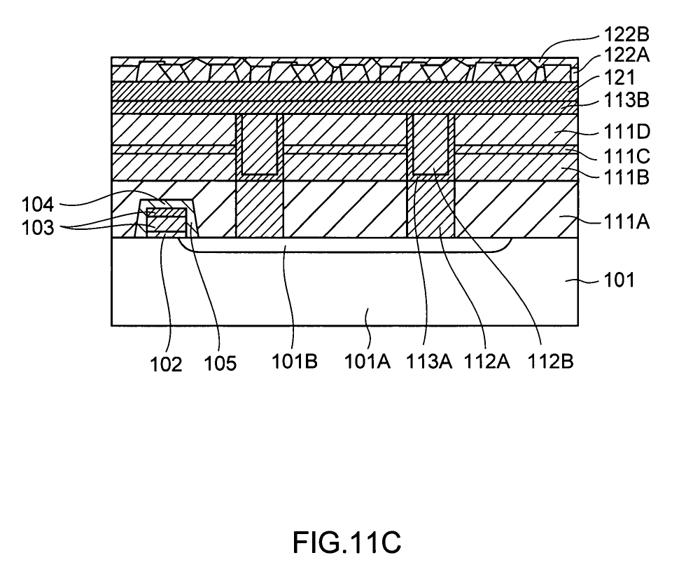

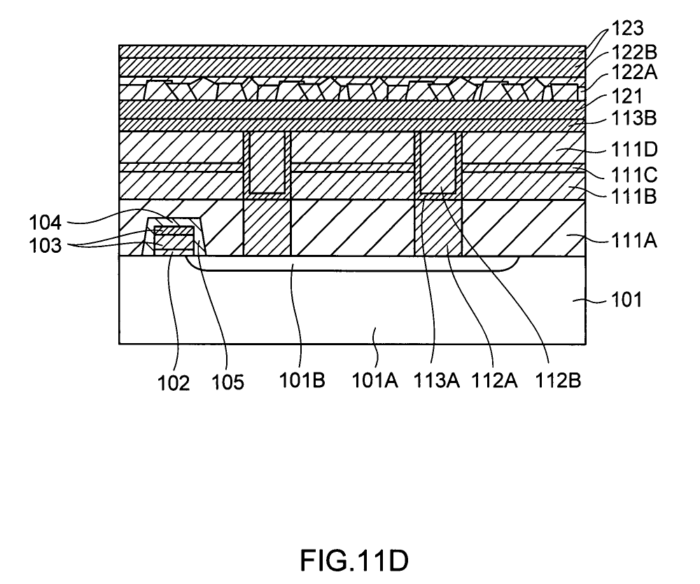

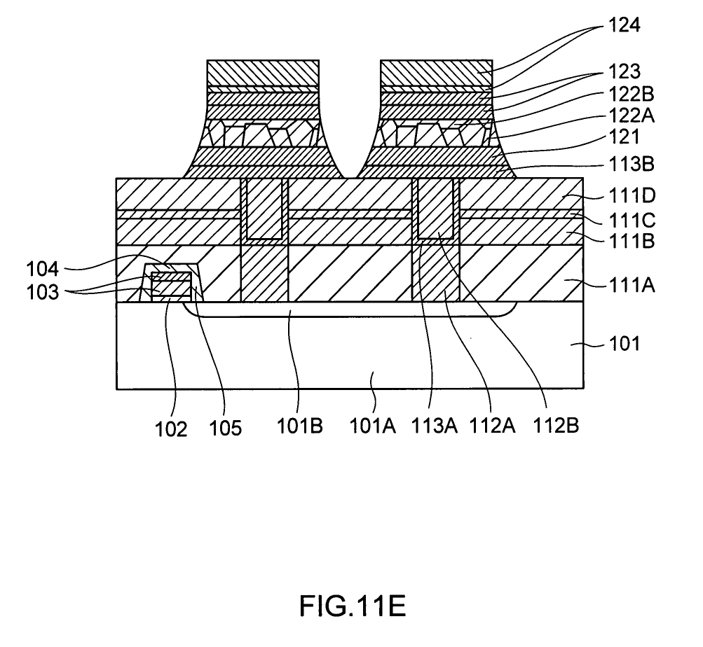

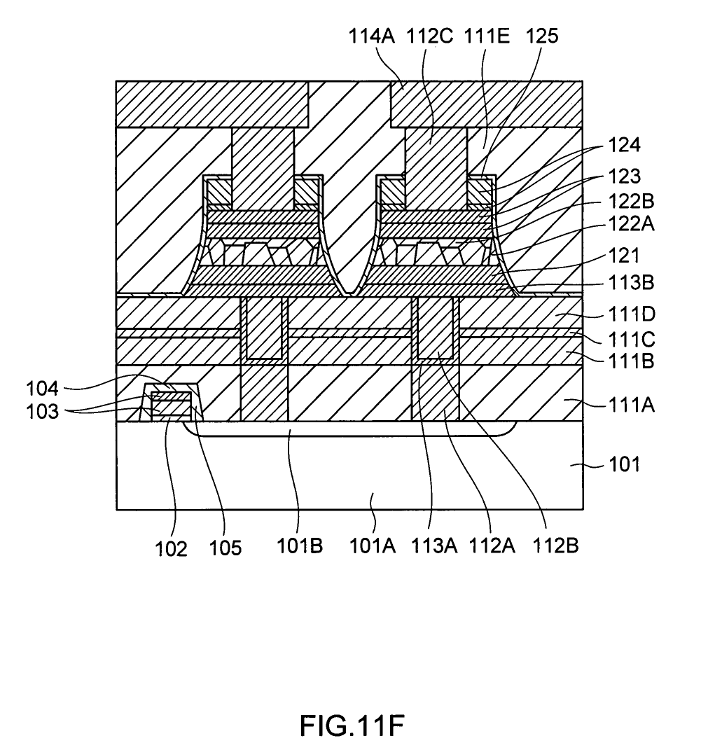

FIGS. 11A to 11F are cross-sectional views showing a manufacturing method of the semiconductor device according to the fifth embodiment. The manufacturing method shown in FIGS. 11A to 11F will be described mainly focusing on its differences from manufacturing method of the first embodiment.

First, as shown in FIG. 11A, a gate insulating film 102, a gate electrode film 103, a cap film 104, a sidewall film 105, interlayer insulating films 111A, 111B, 111C and 111D, plug layers 112A and 112B, and barrier layers 113A and 113B are formed on a (or above) substrate 101 by known methods. A diffusion layer 101A and a source/drain diffusion layer 101B are also formed by known methods.

Next, as shown in FIG. 11B, under the condition that the barrier layer 113B is deposited over the entire surface, an Ir film (lower electrode film 121) is formed on the barrier layer 113B by sputtering method or CVD method. The Ir film is deposited over the entire surface. Then, a first PZT film (first ferroelectric film 122A) is formed on the Ir film by in-situ crystallization of PZT by MOCVD method, using liquid material such that metallo-organic complex is melted in liquid. Thereby, irregularities due to the in-situ crystallization are formed on the surface of the first PZT film. The first PZT is deposited over the entire surface. Then, a second PZT film (second ferroelectric film 122B) is formed on the first PZT film by sputtering method or CVD method. The second PZT film is deposited over the entire surface.

Next, as shown in FIG. 11C, a part of the second ferroelectric film 122B is removed through a planarizing process by CMP method (chemical mechanical polishing method) or etch-back method, to planarize the surface of the second ferroelectric film 122B. In this case, the planarization of the surface of the second ferroelectric film 122B is continued until it reaches the first ferroelectric film 122A. Thereby, both of the “second ferroelectric film 122B” which is partially remaining on the surface of the substrate and the “ferroelectric film 122A” which has started to be exposed on the surface of the substrate, are exposed on the surface of the substrate. The first and second ferroelectric films have a structure in which the second ferroelectric film 122B exists in a concave portion of the first ferroelectric film 122A. An SRO film (lower layer of upper electrode film 123) to be formed on the surface of the substrate next, will contact both the first ferroelectric film 122A and second ferroelectric film 122B.

Next, as shown in FIG. 11D, the SRO film (lower layer of upper electrode film 123) is formed on the first and second PZT films by sputtering method or CVD method. The SRO film is deposited over the entire surface. In the case where the SRO film is formed in an amorphous state, an annealing process such as RTA is performed for crystallization of the SRO film. Then, an IrOₓ film (upper layer of the upper electrode film 123) is formed on the SRO film by sputtering method or CVD method. The IrOₓ film is deposited over the entire surface. In a reducing atmosphere such as hydrogen, the IrOₓ film works as a self-reduced buffer film, and shows high barrier properties against oxygen. Laminated films of the SRO film and IrOₓ film have advantages that the barrier properties against reducing gas are intensified, diffusion of Ir generated by reduction of the IrOₓ into the second PZT film is prevented, and the like. The IrOₓ film may undergo densification, crystallization and the like by a thermal process after deposition.

Next, an aluminum oxide film (lower layer of mask film 124) is formed on the IrOₓ film by sputtering method or CVD method. The aluminum oxide film is deposited over the entire surface. Then, a silicon dioxide film (upper layer of the mask film 124) is formed on the aluminum oxide film by sputtering method or CVD method. The silicon dioxide film is deposited over the entire surface. Then, as shown in FIG. 11E, the upper layer of the mask film 124 is processed by an etching by photolithography method and RIE method. Then, the lower layer of the mask film 124, the upper layer of the upper electrode film 123, the lower layer of the upper electrode film 123, the second ferroelectric film 122B, the first ferroelectric film 122A, the lower electrode film 121 and the barrier layer 113C are processed by an etching by RIE method.

Next, as shown in FIG. 11F, an aluminum oxide film (cover film 125) is formed on the mask film 124 by sputtering method or CVD method. The aluminum oxide film is deposited over the entire surface. Then, a silicon dioxide film (interlayer insulating film 111E) is formed on the aluminum oxide film by sputtering method or CVD method. The silicon dioxide film is deposited over the entire surface. Then, a part of the interlayer insulating film 111E is removed through a planarizing process by CMP method or etch back method, to planarize the surface of the interlayer insulating film 111E. Then, the interlayer insulating film 111E, the cover film 125, the upper layer of the mask film 124 and the lower layer of the mask film 124 are processed by an etching by photolithography method and RIE method, to form a contact hole for embedding a plug layer 112C. Then, the interlayer insulating film 111E is processed by an etching by photolithography method and RIE method, to form a trench for embedding a wiring layer 114A. Then, an annealing process (annealing conditions are oxygen atmosphere, 600 to 650° C., 30 to 60 minutes for example) is performed for recovery of the first PZT film from damage. If the damage is slight, this annealing process may be omitted. Then, member for forming the plug layer 112C and the wiring layer 114A is embedded in the contact hole and the trench by sputtering method or CVD method, to form the plug layer 112C and the wiring layer 114A of a dual damascene structure for connecting adjacent capacitors.

In the fifth embodiment, due to the in-situ crystallization, the surface of the first ferroelectric film 122A is irregular. However, due to the planarizing process performed by utilizing the second ferroelectric film 122B, the surface formed of the first and second ferroelectrics becomes flat, before the upper electrode film 123 is formed on the first and second ferroelectrics. Therefore, the surface of the upper electrode film 123, that is, the interface between the upper electrode film 123 and its upper conductive layer (plug layer 112C), also becomes flat. This improves a joint between the upper electrode film 123 and its upper conductive layer (plug layer 112C). With regard to the flatness of the surface of the upper electrode film 123, it is desirable that the mean roughness of the irregularities (minute irregularities) on the surface of the upper electrode film 123 be 2.0 to 5.0 nm. Thereby, focus in lithography for the upper electrode film 123 becomes even. Further, the RIE processing of the capacitor becomes easier, so that the side surface of the capacitor can be processed to be even. Further, in terms of the electric characteristics and reliability, reducing damage from upward cannot be suffered easily, because coverage of the upper electrode becomes even. Further, it is also possible to suppress adverse influences such that, resulting from the occurrence of electrostatic concentration in a thin part of the ferroelectric film, a leakage current increases, withstand voltage reduces, fatigue characteristics deteriorate, and retention characteristics degrade. These preferred effects become particularly conspicuous when the thickness of the ferroelectric film becomes 100 nm or less. In addition to these example, the above-mentioned various adverse influences which the first ferroelectric film 122A formed by the in-situ crystallization has on the semiconductor device, are prevented by the planarizing process of the second ferroelectric film 122B, which improves the reliability of the semiconductor device and the yield of a product of the semiconductor device.

In the fifth embodiment, it is also possible, in the process shown in FIG. 11B, to form the second ferroelectric film 122B (second PZT film) on the first ferroelectric film 122A (first PZT film) by solution application method, solution dipping method, or bias sputtering method. If the second ferroelectric film 122B is deposited by solution application method, solution dipping method, or bias sputtering method, the surface of the ferroelectrics becomes flat. Therefore, the planarizing process thereafter is not required. That is, the process shown in FIG. 11C is not required. The first and second ferroelectric films have the structure in which the concave portion of the first ferroelectric film 122A is filled with the second ferroelectric film 122B.

FIG. 9 shows a cross-sectional TEM image of a PZT film formed by in-situ crystallization of PZT by MOCVD method. The maximum roughness of the irregularities on the surface of the PZT film of FIG. 9 is about 80 nm. The maximum roughness of the irregularities on the surface of the PZT film is controllable by forming crystal grains as shown in FIG. 9, i.e., PZT grains with rugged surfaces. Area density of such crystal grains on the PZT film of FIG. 9 is 5 to 10 pieces/μm².

The following description will describe details and variations of the first ferroelectric film 122A.

The first ferroelectric film 122A is formed on the lower electrode film 121 by deposition with simultaneous crystallization using the MOCVD method. With regard to the MOCVD of the high-permittivity film and the ferroelectric film, vapor pressure of the material is generally low. Therefore, a solution vaporization method is widely used, which is the method for melting a metallo-organic complex material in an organic solvent, leading it into the carburetor in the solution state at normal temperature and forcibly vaporizing it. In comparison with the solid sublimation method, the solution vaporization method has advantages that it is easy to control a material supply, it is possible to increase deposition speed of the high-permittivity film and the ferroelectric film by increasing the material supplies, it is possible to monitor a remaining amount of the solution with a level sensor, and the like. The conditions of the MOCVD material are as follows: selective deposition should be easy, a high-purity film should be formable with little amounts of carbon and particles remaining in the film, the vapor pressure when it is a liquid should be high and its supply should be easy, it should be stable and storable without changing over time, its toxicity should be low enough to be safe to an environment and a human body, and the like. The first ferroelectric film 122A has the irregularities of which maximum roughness is 50 to 150 nm for example (80 nm for example) formed on its surface.

In the case of forming a PZT-type film as the first ferroelectric film 122A for example, Pb (dpm) 2, Zr (dpm) 4, Zr (O.t—C4H9) 4, Ti (O.i—C3H7) 4 and the like are used as the materials of the first ferroelectric film 122A. These materials are dissolved in THF (tetrahydrofuran) to be liquid materials. Subsequently, the liquid materials are gasified by pumping the inactive gases such as He and Ar as the carrier gases and spraying them to the carburetor. Subsequently, oxygen, dinitrogen monoxide and the like as the oxidizers are introduced into a chamber via the shower plate so as to deposit the first ferroelectric film 122A on the substrate 101 inside the chamber. A solution including Pb, Zr and Ti (cocktail source) may also be used as the material of the first ferroelectric film 122A. In this case, the temperature of the substrate 101 is set as 400 to 650° C., and the composition of the PZT film is controlled by controlling the gas supplies. For example, control is exerted so that the ratio of Pb becomes about 1.15 as the A/B ratio and the Zr/Ti ratio becomes 35/65 so as to deposit the PZT film. In this case, a deposition condition for crystallizing the PZT as the PZT film of the perovskite structure is applied. Here, the PZT is crystallized simultaneously with deposition (in-situ crystallized), which suppresses the defect formation on the interface between the lower electrode film 121 and the first ferroelectric film 122A, such as the positive ion excess, positive ion loss and oxygen loss. This leads to prevention of the deterioration of the ferroelectric characteristics, fatigue characteristics, imprint characteristics and retention characteristics. The thickness of the first ferroelectric film 122A is 70 to 150 nm here. On the other hand, the thickness of the first ferroelectric film 122A may be 50 nm or less. This is intended to reduce the size of the irregularities on the surface of an in-situ crystal film by reducing the thickness of the in-situ crystal film, and thereby utilize the in-situ crystal film of good characteristics while alleviating its adverse influences.

In the case of forming an SBT-type film as the first ferroelectric film 122A for example, Sr (dpm) 2/THF, Bi (C6H5) 3, Bi (CH3) 3, Bi (C2H5) 3, a solid material having phenyl and tolyl, Ta (OC2H5) 5, Nb (OC2H5) 5, Ta (C2H5) 5 and the like are used as the materials of the first ferroelectric film 122A. These liquid materials are gasified by pumping them with the inactive gases such as He and Ar as the carrier gases and spraying them to the carburetor. Or else, these liquid materials are introduced into the carburetor by the bubbling method. Subsequently, oxygen, dinitrogen monoxide and the like as the oxidizers are introduced into the chamber via the shower plate so as to deposit the first ferroelectric film 122A on the substrate 101 inside the chamber. A solution including Sr, Bi, Ta and Nb (cocktail source) may also be used as the material of the first ferroelectric film 122A. In this case, the temperature of the substrate 101 is set as 400 to 650° C., and the composition of the PZT film is controlled by controlling the gas supplies. In this case, a deposition condition for crystallizing the SBT or the SBTN as the SBT film or SBTN film of a Bi layer compound structure is applied. Here, the SBT or the SBTN is crystallized simultaneously with deposition (in-situ crystallized), which suppresses the defect formation on the interface between the lower electrode film 121 and the first ferroelectric film 122A, such as the positive ion excess, positive ion loss and oxygen loss. This leads to prevention of deterioration of the ferroelectric characteristics, fatigue characteristics, imprint characteristics and retention characteristics. The thickness of the first ferroelectric film 122A is 70 to 150 nm here. On the other hand, the thickness of the first ferroelectric film 122A may be 50 nm or less. This is intended to reduce the size of the irregularities on the surface of an in-situ crystal film by reducing the thickness of the in-situ crystal film, and thereby utilize the in-situ crystal film of good characteristics while alleviating its adverse influences.

With regard to specific examples of the first ferroelectric film 122A, a BIT-type film (Bi₄Ti₃O₁₂ or the like) can be named in addition to the PZT-type film (Pb (ZrₓTi₁₋ₓ) O₃ or the like) and the SBT-type film (SrBi₂Ta₂O₉ or the like).

The following description will describe details and variations of the second ferroelectric film 122B.

The second ferroelectric film 122B is formed on the surface of the first ferroelectric film 122A having the irregularities formed thereon by using the CSD (Chemical Solution Deposition) method such as sol-gel method. The second ferroelectric film 122B is desirably the ferroelectric film of the same composition as the first ferroelectric film 122A. However, it may also be a ferroelectric film of a different composition from the first ferroelectric film 122A. For example, in the case where the first ferroelectric film 122A is the PZT-type film, the second ferroelectric film 122B may be either a PZT-type film of a different composition (dopant, Zr/Ti ratio, Pb amount and the like) from the PZT-type film or a film of a type other than the PZT-type. In the case where the second ferroelectric film 122B has the same composition as the first ferroelectric film 122A, they have the same coercive force so as to have the effects that the leakage current generated due to a difference in the coercive force between the films is small and the breakdown voltage is high. In the case where the second ferroelectric film 122B is the ferroelectric film of a different composition from the first ferroelectric film 122A, such as when the first ferroelectric film 122A is a PZT-type film of which Zr/Ti is 30/70 while the second ferroelectric film 122B is a PZT-type film of which Zr/Ti is 40/60, it has the effects that the PZT film can be more easily oriented in accordance with the orientation of the lower electrode (111 orientation for example) so as to increase the amount of polarization, improve the saturation characteristics, and increase the amount of signals. Further, since the second ferroelectric film 122B partially exists, the stress on the interface of the upper electrode is reduced to improve the imprint characteristics and the retention characteristics. Furthermore, nucleation is promoted in the second ferroelectric film portion on domain inversion, so that the effect of facilitating polarization inversion (reducing the coercive force) can be expected. In the case where the second ferroelectric film 122B is the PZT film, an amorphous film is deposited on the first ferroelectric film 122 by sol-gel method using a metal alkoxide solution such as lead acetate hydrate, Ti isopropoxide and Zr butoxide, by MOD method using a carboxylic acid metallic salt, or the like. After the amorphous film desiccates, the crystallization annealing is performed in oxygen atmosphere by a process such as RTO. In this case, it is also possible to repeat the application, desiccation and crystallization annealing process. It is possible to form the second ferroelectric film 122B by solution application method such as sol-gel method or MOD method, solution dipping method, sputtering method such as bias sputtering method, CVD method such as mist CVD method, evaporation method or the like. In the case where the second ferroelectric film 122B is deposited by solution application method, solution dipping method, or bias sputtering method, the film having a flat surface formed of the first and second ferroelectrics is deposited. The mean roughness (Ra) of the irregularities on the surface of the second ferroelectric film 122B is about a few nm which is 5 nm or less. This value is smaller than the mean roughness of the irregularities on the surface of an MOCVD film.

As described above, according to the embodiments of the present invention, it is possible, with regard to a semiconductor device including a ferroelectric capacitor, to secure characteristics and reliability of the capacitor.

It is noted that variations of embodiments of the present invention are provided as follows.

A variation of embodiments of the present invention is, for example, a manufacturing method of a semiconductor device, including:

forming a lower electrode film for a capacitor above a substrate;

forming a ferroelectric film on the lower electrode film by deposition-simultaneous crystallization; and

forming an upper electrode film on the ferroelectric film by solution application method, by solution dipping method, by bias sputtering method, or by planarizing the surface of the upper electrode film through a planarizing process.

Another variation of embodiments of the present invention is, for example, a semiconductor device, including:

a lower electrode film for a capacitor formed on a substrate;

a ferroelectric film formed on the lower electrode film and having irregularities on the top surface of the ferroelectric film; and

an upper electrode film for the capacitor formed on the ferroelectric film, the maximum of irregularity height on the top surface of the upper electrode film being smaller than that of the ferroelectric film.

Another variation of embodiments of the present invention is, for example, a semiconductor device, including:

a lower electrode film for a capacitor formed on a substrate;

a ground film formed on the lower electrode film, the ground film being an oriented film oriented in a specific direction or a crystal film formed by crystallization of amorphous;

a ferroelectric film formed on the ground film; and

an upper electrode film for the capacitor formed on the ferroelectric film.

1. A manufacturing method of a semiconductor device, comprising:
forming a lower electrode film for a capacitor above a substrate;
forming a ferroelectric film on the lower electrode film by deposition-simultaneous crystallization;
forming a dummy film on the ferroelectric film;
removing the dummy film and a part of the ferroelectric film through a planarizing process to planarize the surface of the ferroelectric film; and
forming an upper electrode film for the capacitor on the ferroelectric film.

2. A manufacturing method of a semiconductor device, comprising:
forming a lower electrode film for a capacitor above a substrate;
forming a first ferroelectric film on the lower electrode film by deposition-simultaneous crystallization;
forming a second ferroelectric film on the first ferroelectric film by solution application method, by solution dipping method, by bias sputtering method, or by planarizing the surface of the second ferroelectric film through a planarizing process; and
forming an upper electrode film for the capacitor on the second ferroelectric film.

3. A manufacturing method of a semiconductor device, comprising:
forming a lower electrode film for a capacitor above a substrate;
forming, as a ground film, an oriented film oriented in a specific direction or a crystal film formed by crystallization of amorphous, on the lower electrode film; and
forming a ferroelectric film on the ground film by deposition-simultaneous crystallization.

4. The manufacturing method according to claim 1, wherein the dummy film is a ferroelectric film.

5. The manufacturing method according to claim 1, wherein the dummy film is a ferroelectric film of the same composition as the ferroelectric film.

6. The manufacturing method according to claim 1, wherein the ferroelectric film is formed by deposition-simultaneous crystallization of ferroelectric by MOCVD (Metal Organic Chemical Vapor Deposition) method.

7. The manufacturing method according to claim 1, wherein the ferroelectric film is a PZT film, an SBT film, or a BIT film.

8. The manufacturing method according to claim 1, wherein the thickness of the ferroelectric film is 100 nm or less.

9. The manufacturing method according to claim 1, wherein the mean roughness of irregularities on the surface of the upper electrode film is 2.0 to 5.0 nm.

10. The manufacturing method according to claim 1, wherein the capacitor is a stack-type capacitor.

11. The manufacturing method according to claim 2, wherein the first ferroelectric film is formed by deposition-simultaneous crystallization of ferroelectric by MOCVD (Metal Organic Chemical Vapor Deposition) method.

12. The manufacturing method according to claim 2, wherein the first ferroelectric film is a PZT film, an SBT film, or a BIT film.

13. The manufacturing method according to claim 2, wherein the thickness of the first ferroelectric film is 70 to 150 nm.

14. The manufacturing method according to claim 2, wherein the thickness of the first ferroelectric film is 50 nm or less.

15. The manufacturing method according to claim 2, wherein the maximum roughness of irregularities on the surface of the first ferroelectric film is 50 to 150 nm.

16. The manufacturing method according to claim 2, wherein the second ferroelectric film is a ferroelectric film of the same composition as the first ferroelectric film.

17. The manufacturing method according to claim 2, wherein the mean roughness of irregularities on the surface of the upper electrode film is 2.0 to 5.0 nm.

18. The manufacturing method according to claim 3, wherein a conductive film oriented in a specific direction is formed as the oriented film.

19. The manufacturing method according to claim 3, wherein a ferroelectric film formed by crystallization of amorphous is formed as the crystal film.

20. A semiconductor device, comprising:
a lower electrode film for a capacitor formed on a substrate;
a first ferroelectric film formed on the lower electrode film and having irregularities on the top surface of the first ferroelectric film;
a second ferroelectric film formed between the first ferroelectric film and an upper electrode film for the capacitor, the maximum of irregularity height on the top surface of the second ferroelectric film being smaller than that of the first ferroelectric film; and
the upper electrode film for the capacitor formed on the second ferroelectric film.
